(19) United States
(12) Patent Application Publication
(10) Pub. No.: US 2026/0293778 A1
(43) Pub. Date: Sep. 24, 2026

(54) SEMICONDUCTOR MEMORY DEVICE AND METHOD FOR MANUFACTURING THE SAME

(71) Applicant: SAMSUNG ELECTRONICS CO., LTD., Suwon-si (KR)

(72) Inventors: Byung Chul LEE, Suwon-si (KR); Jun Hyoung KIM, Suwon-si (KR); Joon Young KWON, Suwon-si (KR); Won Jin KIM, Suwon-si (KR); Ji Young KIM, Suwon-si (KR); Suk Kang SUNG, Suwon-si (KR)

(73) Assignee: SAMSUNG ELECTRONICS CO., LTD., Suwon-si (KR)

(21) Appl. No.: 19/566,289

(22) Filed: Mar. 13, 2026

(30) Foreign Application Priority Data
Mar. 19, 2025 (KR) 10-2025-0035405

(51) Int. Cl. H10W 90/20; G11C 16/04; H10B 41/10; H10B 41/27; H10B 41/35; H10B 43/10; H10B 43/27; H10B 43/35; H10D 80/30

(52) U.S. Cl. CPC H10W 90/297; G11C 16/0483; H10B 41/10; H10B 41/27; H10B 41/35; H10B 43/10; H10B 43/27; H10B 43/35; H10D 80/30

(57) ABSTRACT

A semiconductor memory device includes a cell area and a peripheral circuit area disposed on the cell area. The cell area includes a stack structure including gate electrodes stacked in a first direction, and a channel structure disposed in the stack structure and extending in the first direction. The peripheral circuit area includes a well structure including a first surface and a second surface facing each other, the well structure including a first well area and a second well area disposed on the first surface, a first transistor being disposed in the first well area, and a second transistor being disposed in the second well area, an isolation structure that isolates the first well area and the second well area from each other, a stopper structure disposed on the isolation structure, and a through-structure that partially extends into the stopper structure in the first direction.

### CROSS-REFERENCE TO RELATED APPLICATION

This application claims priority from Korean Patent Application No. 10-2025-0035405 filed on Mar. 19, 2025 in the Korean Intellectual Property Office, the contents of which being herein incorporated by reference in its entirety.

### BACKGROUND

The present disclosure relates to a semiconductor memory device, and a method for manufacturing the same.

In order to meet high performance and low price of a semiconductor memory device as demanded by consumers, it is required to increase integration of the semiconductor memory device. The integration of the semiconductor memory devices is an important factor in determining a price thereof. Thus, the semiconductor memory device having increased integration is particularly required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase is limited. Accordingly, three-dimensional semiconductor memory devices including three-dimensionally arranged memory cells have been proposed.

### SUMMARY

It is an aspect to provide a semiconductor memory device with improved electrical properties and reliability.

It is another aspect to provide a method for manufacturing a semiconductor memory device with improved electrical properties and reliability.

According to an aspect of one or more embodiments, there is provided a semiconductor memory device comprising a cell area; and a peripheral circuit area disposed on the cell area. The cell area includes a stack structure including a plurality of gate electrodes stacked in a first direction; and a channel structure disposed in the stack structure and extending in the first direction. The peripheral circuit area includes a well structure including a first surface and a second surface facing each other, wherein the well structure includes a first well area and a second well area disposed on the first surface, wherein a first transistor is disposed in the first well area, and a second transistor is disposed in the second well area; an isolation structure that isolates the first well area and the second well area from each other; a stopper structure disposed on the isolation structure; and a through-structure that at least partially extends into the stopper structure in the first direction.

According to another aspect of one or more embodiments, there is provided a semiconductor memory device comprising a cell area; and a peripheral circuit area disposed on the cell area. The cell area includes a stack structure including a plurality of gate electrodes stacked in a first direction; and a channel structure disposed in the stack structure and extending in the first direction. The peripheral circuit area includes a well structure including a first well area of a first conductivity type and a second well area of a second conductivity type different from the first conductivity type; an isolation structure disposed between the first well area and the second well area and including an insulating material; a first transistor disposed on the first well area; a second transistor disposed on the second well area; a first interlayer insulating film disposed on the well structure, wherein a first wiring structure is disposed in the first interlayer insulating film; a second interlayer insulating film disposed between the well structure and the cell area, wherein a second wiring structure is disposed in the second interlayer insulating film; a conductive structure disposed on the isolation structure; a first through-via that is disposed in the first interlayer insulating film and that extends in the first direction and contacts the conductive structure; and a second through-via that is disposed in the second interlayer insulating film and that extends in the first direction and contacts the conductive structure.

According to yet another aspect of one or more embodiments, there is provided a semiconductor memory device comprising a cell area; and a peripheral circuit area disposed on the cell area. The cell area includes a stack structure including a plurality of gate electrodes stacked in a first direction; a channel structure that is disposed in the stack structure and that extends in the first direction; a bit line that extends in a second direction different from the first direction and that is connected to the channel structure; and a first bonding pad disposed on the bit line. The peripheral circuit area includes a well structure including a first well area of a first conductivity type and a second well area of a second conductivity type different from the first conductivity type; an isolation structure that isolates the first well area from the second well area; a PMOS transistor disposed on the first well area; a NMOS transistor disposed on the second well area; a first interlayer insulating film disposed on the well structure; a second interlayer insulating film disposed between the well structure and the cell area; a second bonding pad that is disposed on the second interlayer insulating film and that is bonded to the first bonding pad; a bias structure including a first bias area connected to the first well area and a second bias area connected to the second well area; a conductive structure disposed on the isolation structure; a first through-via that is disposed in the first interlayer insulating film and that extends in the first direction and contacts the conductive structure; and a second through-via that is disposed in the second interlayer insulating film and that extends in the first direction and contacts the conductive structure.

According to still another aspect of one or more embodiments, there is provided a method for manufacturing a semiconductor memory device comprising providing a base substrate including a first surface and a second surface facing each other, forming a first well area and a second well area and an isolation structure on the first surface of the base substrate such that the isolation structure is disposed between the first well area and the second well area, the first well area and the second well area including different conductive materials, forming a conductive material layer on the first well area and the second well area and the isolation structure, performing an etching process on the conductive material layer to form a first gate structure on the first well area, a second gate structure on the second well area, and a conductive structure on the isolation structure, forming a first through-via at least partially extending into the conductive structure, and forming a second through-via extending through the isolation structure and extending at least partially into the conductive structure.

### BRIEF DESCRIPTION OF DRAWINGS

The above and other will become more apparent by describing in detail embodiments thereof with reference to the attached drawings, in which:

FIG. 1 is an illustrative block diagram for illustrating a semiconductor memory device according to some embodiments;

FIG. 2 is an illustrative circuit diagram for illustrating a semiconductor memory device according to some embodiments;

FIG. 3 is an example plan view for illustrating a semiconductor memory device according to some embodiments;

FIG. 4 is a cross-sectional view taken along a line A-A of FIG. 3;

FIG. 5 is an enlarged view of an area P1 of FIG. 4;

FIG. 6 is an enlarged view of an area P2 of FIG. 4;

FIG. 7 is an enlarged view of an area P3 of FIG. 4;

FIGS. 8 to 12 are diagrams corresponding to the enlarged view illustrated in FIG. 5 for illustrating a semiconductor memory device according to some embodiments;

FIG. 13 is an enlarged view of an area Q1 of FIG. 5;

FIGS. 14 and 15 are diagrams corresponding to the enlarged view illustrated in FIG. 13 for illustrating a semiconductor memory device according to some embodiments;

FIGS. 16 to 18 are example layout diagrams for illustrating a semiconductor memory device according to some embodiments;

FIGS. 19 and 20 are cross-sectional views illustrating a semiconductor memory device according to some embodiments;

FIGS. 21 and 22 are cross-sectional views illustrating a semiconductor memory device according to some embodiments;

FIGS. 23 to 25 are example layout diagrams for illustrating a semiconductor memory device according to some embodiments;

FIGS. 26 to 35 are diagrams of intermediate structures corresponding to intermediate steps of a method for manufacturing a semiconductor memory device according to some embodiments;

FIG. 36 is an example block diagram for illustrating an electronic system according to some embodiments; and

FIG. 37 is an example perspective view illustrating an electronic system according to some embodiments.

### DETAILED DESCRIPTION

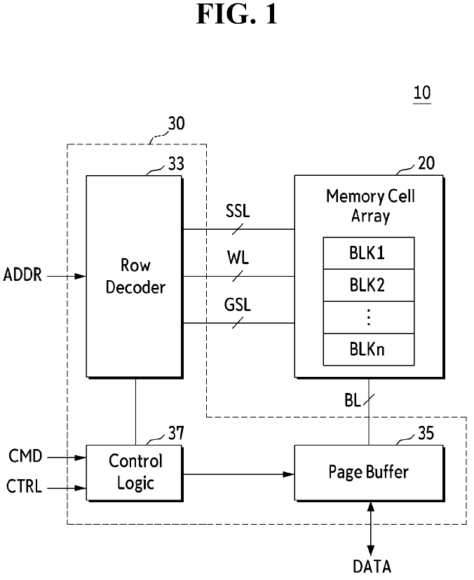

FIG. 1 is an illustrative block diagram for illustrating a semiconductor memory device according to some embodiments. As used in this specification, a phrase using the form “at least one of A, B, or C” includes within its scope “only A”, “only B”, “only C”, “A and B”, “A and C”, “B and C” and “A, B, and C.”

Referring to FIG. 1, a semiconductor device 10 according to some embodiments may include a memory cell array 20 and a peripheral circuit 30. In some embodiments, the peripheral circuit 30 may include a row decoder 33, a page buffer 35, and control logic 37.

The memory cell array 20 may include a plurality of memory cell blocks BLK1 to BLKn. Each of the memory cell blocks BLK1 to BLKn may include a plurality of memory cells. The memory cell array 20 may be connected to the peripheral circuit 30 via a bit-line BL, a word-line WL, at least one string select line SSL, and at least one ground select line GSL. Specifically, the memory cell blocks BLK1 to BLKn may be connected to the row decoder 33 via the word-line WL, the string select line SSL, and the ground select line GSL. Further, the memory cell blocks BLK1 to BLKn may be connected to the page buffer 35 via the bit-line BL.

The peripheral circuit 30 may receive an address ADDR, a command CMD, and a control signal CTRL from an external device that is external to the semiconductor device 10, and may transmit and receive data DATA to and from an external device to the semiconductor device 10. Although not shown, the peripheral circuit 30 may further include various sub-circuits such as an input/output circuit, a voltage generation circuit that generates various voltages for an operation of the semiconductor device 10, and an error correction circuit that corrects an error of the data DATA read from the memory cell array 20.

The control logic 37 may be connected to the row decoder 33, the page buffer 35, the input/output circuit, and the voltage generation circuit, etc. The control logic 37 may control overall operations of the semiconductor device 10. The control logic 37 may generate various internal control signals used in the semiconductor device 10 in response to the control signal CTRL. For example, the control logic 37 may adjust a voltage level of a voltage supplied to the word-line WL and the bit-line BL when performing a memory operation such as a program operation or an erase operation.

The row decoder 33 may select at least one of the plurality of memory cell blocks BLK1 to BLKn in response to the address ADDR, and may select at least one word-line WL, at least one string select line SSL, or at least one ground select line GSL of the selected at least one memory cell block BLK1 to BLKn. Further, the row decoder 33 may transmit a voltage for performing a memory operation to the word-line WL of the selected at least one memory cell block BLK1 to BLKn.

The page buffer 35 may be connected to the memory cell array 20 via the bit-line BL. The page buffer 35 may operate as a writer driver or a sense amplifier. Specifically, when performing a program operation, the page buffer 35 operates as the writer driver to apply a voltage based on the data DATA to be stored in the memory cell array 20 to the bit-line BL. When performing a read operation, the page buffer 35 may operate as the sense amplifier to detect the data DATA stored in the memory cell array 20.

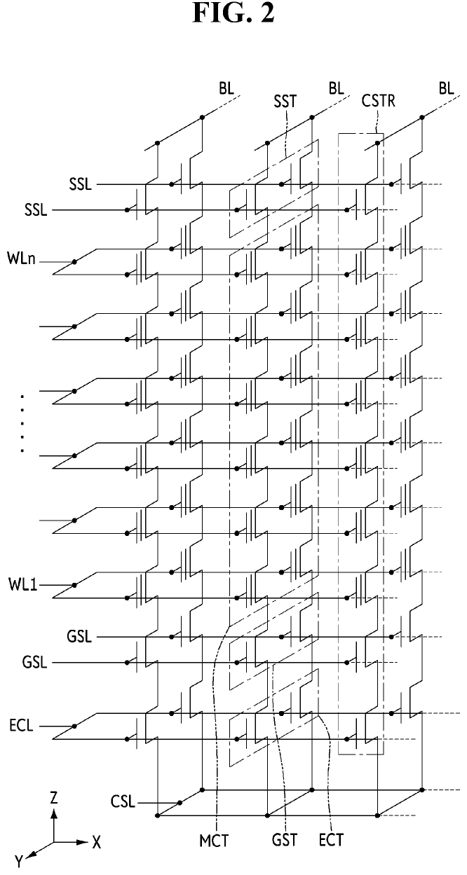

FIG. 2 is an illustrative circuit diagram for illustrating a semiconductor memory device according to some embodiments.

Referring to FIG. 2, a memory cell array (e.g., the memory cell array 20 in FIG. 1) of a semiconductor memory device according to some embodiments may include a common source line CSL, a plurality of bit-lines BL, and a plurality of cell strings CSTR.

The common source line CSL may extend in a second direction Y. In some embodiments, a plurality of common source lines CSL may be arranged in a two-dimensional manner. For example, the plurality of common source lines CSL may be spaced from each other, and each of the plurality of common source lines CSL may extend in the second direction Y. The same voltage may be applied to the common source lines CSL. In some embodiments, different voltages may be individually applied to be the common source lines CSL.

The plurality of bit-lines BL may be arranged in a two-dimensional manner. For example, the plurality of bit-lines BL may be spaced from each other and each of the plurality of bit-lines BL may extend in a first direction X perpendicular to the second direction Y. The plurality of cell strings CSTR may be connected in parallel to each of the bit-lines BL. The cell strings CSTR may be connected to the common source line CSL. That is, the plurality of cell strings CSTR may be disposed between the bit-lines BL and the common source line CSL.

Each of the cell strings CSTR may include a ground select transistor GST connected to the common source line CSL, a string select transistor SST connected to the bit-line BL, and a plurality of memory cell transistors MCT disposed between the ground select transistor GST and the string select transistor SST. Each of the memory cell transistors MCT may include a data storage element. The ground select transistor GST, the string select transistor SST and the memory cell transistors MCT may be connected in series to each other.

The common source line CSL may be commonly connected to sources of the ground select transistors GST. Further, a ground select line GSL, a plurality of word-lines WL1 to WLn and a string select line SSL may be disposed between the common source line CSL and the bit-line BL. The ground select line GSL may act as a gate electrode of the ground select transistor GST. The word-lines WL1 to WLn may be respectively used as gate electrodes of the memory cell transistors MCT. The string select line SSL may act as a gate electrode of the string select transistor SST.

In some embodiments, an erase control transistor ECT may be disposed between the common source line CSL and the ground select transistor GST. The common source line CSL may be commonly connected to sources of the erase control transistors ECT. Further, an erase control line ECL may be disposed between the common source line CSL and the ground select line GSL. The erase control line ECL may act as a gate electrode of the erase control transistor ECT. The erase control transistors ECT may generate gate induced drain leakage (GIDL) to execute an erase operation of the memory cell array.

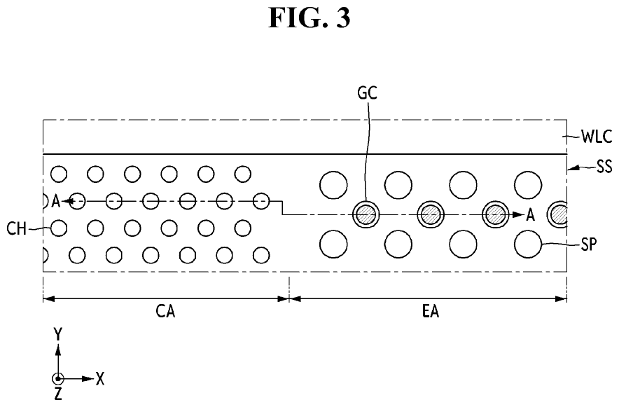

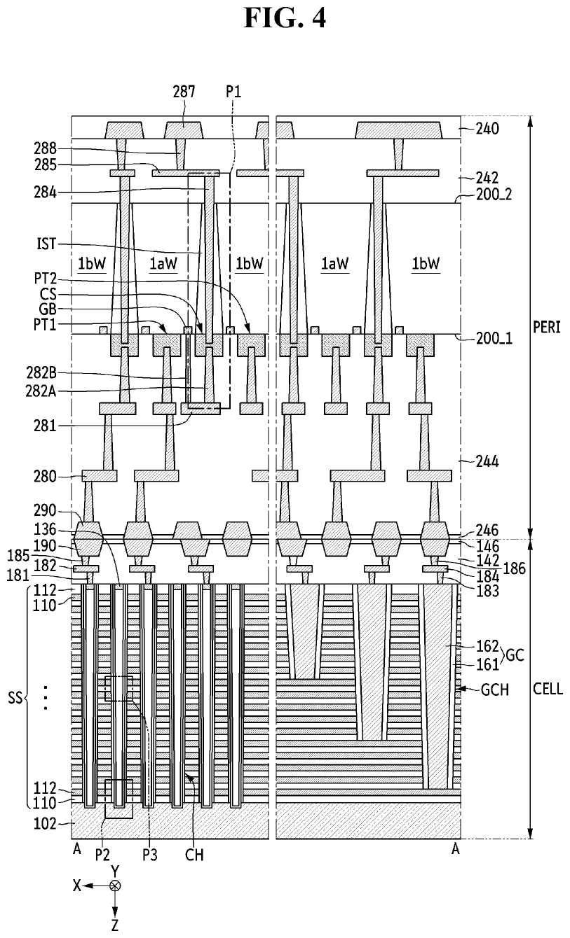

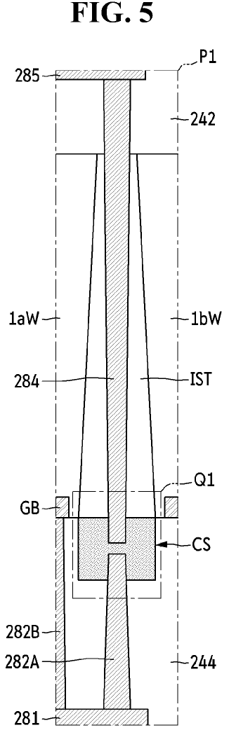

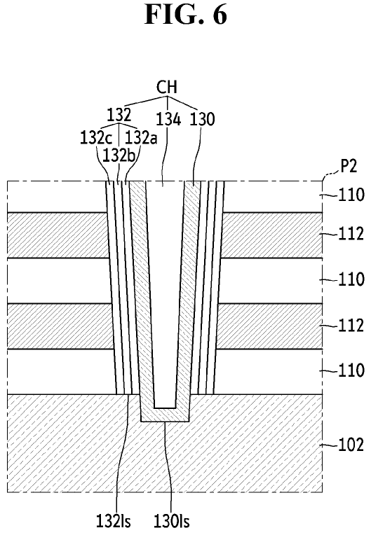

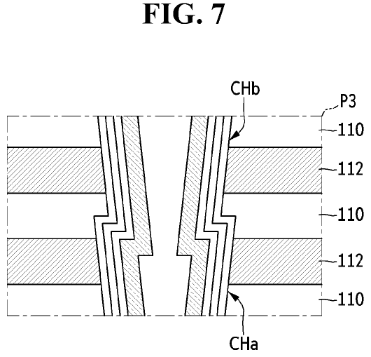

FIG. 3 is an example plan view for illustrating a semiconductor memory device according to some embodiments. FIG. 4 is a cross-sectional view taken along a line A-A of FIG. 3. FIG. 5 is an enlarged view of an area P1 of FIG. 4. FIG. 6 is an enlarged view of an area P2 of FIG. 4. FIG. 7 is an enlarged view of an area P3 of FIG. 4.

Referring to FIGS. 3 and 4, the semiconductor memory device according to some embodiments may include a memory cell area CELL and a peripheral circuit area PERI.

The memory cell area CELL may include a cell substrate 102, a stack structure SS, a channel structure CH, a word line cutting structure WLC, a gate contact GC, a support pattern SP, a cell interlayer insulating film 142, a bit line 182, and a first bonding pad 190.

The cell substrate 102 may include a cell array area CA and an extension area EA.

A memory cell array (e.g., the memory cell array 20 of FIG. 1) including a plurality of memory cells may be disposed on the cell array area CA. For example, the stack structure SS, the channel structure CH, the word line cutting structure WLC, the gate contact GC, the support pattern SP, the cell interlayer insulating film 142, the bit line 182, and the first bonding pad 190, which will be described later, may be disposed on the cell array area CA. In the following description, a surface of the cell substrate 102 on which the memory cell array is disposed may be referred to as a front surface or a front side of the cell substrate 102. Conversely, a surface of the cell substrate 102 opposite to the front surface of the cell substrate 102 may be referred to as a back surface, a rear surface, a back side or a rear side of the cell substrate 102.

The extension area EA may be disposed around the cell array area CA. The extension area EA may be adjacent to the cell array area CA in the first direction X. Although one cell array area CA and one extension area EA are illustrated in FIG. 3, a plurality of cell array areas CA and a plurality of extension areas EA may be present. While the extension area EA is illustrated as adjacent to the cell array area CA on one side of the cell array area CA in FIG. 3, in some embodiments, the extension area EA may be disposed to surround the cell array area CA. For example, in some embodiments, the extension area EA may surround the cell array area CA on all sides thereof in the view illustrated in FIG. 3.

The cell array area CA may be an area in which a plurality of channel structures (e.g., the channel structure CH of FIG. 4) to be described later are formed. The extension area EA may be an area in which a plurality of gate contacts GC (see FIG. 4) to be described later are formed. The plurality of channel structures CH and the plurality of gate contacts GC may be disposed on the cell substrate 102.

The cell substrate 102 may include, for example, a semiconductor substrate such as a silicon substrate, a germanium substrate, or a silicon-germanium substrate. In some embodiments, the cell substrate 102 may include a Silicon-On-Insulator (SOI) substrate or a Germanium-On-Insulator (GOI) substrate. In some embodiments, the cell substrate 102 may contain impurities. For example, the cell substrate 102 may contain n-type impurities (e.g., phosphorus (P), arsenic (As), and/or the like).

In some embodiments, the cell substrate 102 may include a source layer. For example, the source layer of the cell substrate 102 may be provided in the cell array area CA. In some embodiments, the source layer of the cell substrate 102 may be formed on the cell array area CA, and may not be formed on the extension area EA.

The source layer of the cell substrate 102 may include a conductive material, for example, doped polysilicon or a metal. However, embodiments of the present disclosure are not limited thereto. The source layer of the cell substrate 102 may be provided as a common source line (e.g., the common source line CSL of FIG. 2) of the semiconductor memory device.

The stack structure SS may be disposed on the front surface of the cell substrate 102. The stack structure SS may include a plurality of gate electrodes 112 and a plurality of mold insulating films 110 stacked on the cell substrate 102. In some embodiments, the plurality of gate electrodes 112 may be interleaved with the plurality of mold insulating films 110 as illustrated in FIG. 4. Each gate electrode 112 and each mold insulating film 110 may have a layered structure extending parallel to the front surface of the cell substrate 102. The gate electrodes 112 may be sequentially stacked on the cell substrate 102 so as to be spaced apart from each other via the mold insulating film 110.

Hereinafter, a thickness and a height may be based on a third direction Z. The third direction Z may intersect a plane defined by the first direction X and the second direction Y in a perpendicular manner thereto. The third direction Z may be a direction perpendicular to the front surface of the cell substrate 102. The first direction X and the second direction Y may be parallel to the front surface of the cell substrate 102. As used herein, the third direction Z may be referred to as a vertical direction.

In some embodiments, the gate electrode 112 may include a ground select line (e.g., the ground select line GSL of FIG. 2), word lines (e.g,. the word lines WL1 to WLn of FIG. 2), an erase control line (e.g., the erase control line ECL of FIG. 2), and a string select line (e.g., the string select line SSL of FIG. 2) sequentially stacked on the cell substrate 102. The number and arrangement of the ground select line (e.g., the ground select line GSL of FIG. 2), the word lines (e. g,. the word lines WL1 to WLn of FIG. 2), the erase control line (e.g., the string select line ECL of FIG. 2), and the string select line (e.g., the string select line SSL of FIG. 2) are merely examples, and are not limited to those illustrated. In some embodiments, the erase control line ECL (see FIG. 2) may be omitted. In some embodiments, the gate electrode 112 may further include a dummy word line.

Each of the gate electrodes 112 may include a conductive material, for example, a metal such as tungsten (W), cobalt (Co), nickel (Ni), or the like, or a semiconductor material such as silicon. However, embodiments of the present disclosure are not limited thereto.

The mold insulating films 110 and the gate electrodes 112 may be alternately stacked on top of each other. The mold insulating film 110 may include an insulating material, for example, at least one of silicon oxide, silicon nitride, or silicon oxynitride. However, embodiments of the present disclosure are not limited thereto.

The channel structure CH may be disposed on the cell array area CA. Each of the plurality of channel structures CH may extend in the third direction Z to extend through the stack structure SS. For example, the channel structure CH may be a structure having a pillar shape (e.g., a cylindrical shape) extending in the third direction Z. Accordingly, the channel structure CH may intersect each of the gate electrodes 112. In some embodiments, a width of the channel structure CH may decrease as the channel structure CH extends toward the cell substrate 102.

As illustrated in FIG. 6, the channel structure CH may include a channel pattern 130 and a channel pattern insulating film 132.

The channel pattern 130 may extend in the third direction Z to extend through the stack structure SS. In an embodiment, the channel pattern 130 may have, for example, a cup shape. In some embodiments, the channel pattern 130 may have various shapes such as a cylindrical shape, a square pillar shape, a solid pillar shape, or the like.

The channel pattern 130 may include, for example, a semiconductor material such as single crystal silicon, polycrystalline silicon, an organic semiconductor, and/or a carbon nanostructure.

The channel pattern insulating film 132 may be interposed between the channel pattern 130 and each of the gate electrodes 112. For example, the channel pattern insulating film 132 may extend along at least a portion of an outer side surface of the first channel pattern 130.

In some embodiments, the channel pattern insulating film 132 may include of multiple films. For example, as illustrated in FIG. 6, the channel pattern insulating film 132 may include a first insulating film 132a, a second insulating film 132b, and a third insulating film 132c sequentially stacked on an outer side surface of the channel pattern 130.

In an embodiment, the first insulating film 132a may include oxide, the second insulating film 132b may include nitride, and the third insulating film 132c may include oxide. In an embodiment, the first insulating film 132a may be a tunnel insulating film, the second insulating film 132b may be a charge storage film, and the third insulating film 132c may be a blocking insulating film.

The first insulating film 132a may include, for example, silicon oxide or a high-k material having a higher dielectric constant than a dielectric constant of silicon oxide (e.g., aluminum oxide (Al₂O₃), hafnium oxide (HfO₂)). The second insulating film 132b may include, for example, silicon nitride. The third insulating film 132c may include, for example, silicon oxide or a high-k material having a higher dielectric constant than a dielectric constant of silicon oxide (e.g., aluminum oxide (Al₂O₃), hafnium oxide (HfO₂)).

In some embodiments, the channel structure CH may further include a filling pattern 134. The filling pattern 134 may fill the inside of the channel pattern 130 having a cup shape. The channel pattern 130 may surround an outer sidewall of the filling pattern 134. The filling pattern 134 may include an insulating material. For example, in an embodiment, the filling pattern 134 may include silicon oxide.

The source layer of the cell substrate 102 may be electrically connected to the channel pattern 130 of each channel structure CH. In some embodiments, a portion of the channel pattern 130 may be disposed in the source layer of the cell substrate 102. A lower surface 130ls of the channel pattern 130 may be disposed in the source layer of the cell substrate 102.

The channel pattern insulating film 132 may extend along a portion of the side surface of the channel pattern 130. In an embodiment, the channel pattern insulating film 132 may not cover a lower portion of the channel pattern 130. The channel pattern insulating film 132 may not cover the lower surface 130ls of the channel pattern 130 and a portion of the side surface of the channel pattern 130, as illustrated in FIG. 6. The lower surface 130ls of the channel pattern 130 may be positioned at a lower vertical level than a vertical level of the lower surface 132ls of the channel pattern insulating film 132. The lower surface 130ls of the channel pattern 130 may be in contact with the source layer of the cell substrate 102. A portion of the side surface of the channel pattern 130 may be in contact with the source layer of the cell substrate 102.

For example, the lower surface 132ls of the channel pattern insulating film 132 may be flat. In some embodiments, for example, the lower surface 132ls of the channel pattern insulating film 132 may have a step. For example, the lower surface of the first insulating film 132a may be positioned at a lower vertical level than a vertical level of a lower surface of the second insulating film 132b, and the lower surface of the second insulating film 132b may be positioned at a lower vertical level than a vertical level of a lower surface of the third insulating film 132c.

In some embodiments, the channel structure CH may further include a channel pad 136 (see FIG. 4). The channel pad 136 may be electrically connected to the channel pattern 130. The channel pad 136 may include, for example, doped polysilicon.

In some embodiments, the plurality of channel structures CH may be arranged in a zigzag manner or a honeycomb form. For example, as illustrated in FIG. 3, the plurality of channel structures CH may be arranged in a staggered manner in each of the first direction X and the second direction Y parallel to the upper surface of the cell substrate 102. The channel structure CH having the staggered structure may further improve the integration of the semiconductor memory device. The number and arrangement of the channel structures CH are only examples and are not limited to those shown.

Referring to FIG. 7, in some embodiments, the channel structure CH may include a first channel CHa and a second channel CHb connected to each other. For example, the channel structure CH may be formed by performing a process to form the first channel CHa and performing a process to form the second channel CHb. The first channel CHa may be a lower portion of the channel structure CH, and the second channel CHb may be an upper portion of the channel structure CH. At a boundary between the first channel CHa and the second channel CHb, a width of the first channel CHa may be greater than a width of the second channel CHb. The channel structure CH may have a bent portion at the boundary between the first channel CHa and the second channel CHb.

A word line located near the boundary between the first channel CHa and the second channel CHb may be a dummy word line. For example, the boundary between the first channel CHa and the second channel CHb may be positioned between a word line WLk (where k is a natural number smaller than n) and a word line WL(k+1). In this regard, each of the word line WLk (where k is a natural number smaller than n) and the word line WL(k+1) may be the dummy word line. In this case, data may not be stored in memory cells connected to the dummy word line. In some embodiments, the number of pages page corresponding to memory cells connected to the dummy word line may be smaller than the number of pages corresponding to memory cells connected to a general word line. A voltage level applied to the dummy word line may be different from a voltage level applied to the general word line.

Referring back to FIGS. 3 and 4, the word line cutting structure WLC may extend in the first direction X to cut the stack structure SS on the cell array area CA and the extension area EA. Although not shown specifically, a plurality of word line cutting structures WLC may be spaced apart from each other in the second direction Y and may extend in the first direction X and in a parallel manner to each other. The stack structure SS may be divided by the word line cutting structure WLC into portions respectively constituting a plurality of memory cell blocks (e.g., the memory cell blocks BLK1 to BLKn of FIG. 1). For example, two adjacent word line cutting structures WLC may define one memory cell block therebetween. The plurality of channel structures CH may be disposed in each of the memory cell blocks defined by the word line cutting structure WLC. Although not specifically shown, a width of the word line cutting structure WLC may decrease as the word line cutting structure WLC extends toward the cell substrate 102 (e.g., in the third direction Z).

The word line cutting structure WLC may extend in the first direction X to cut the source layer of the cell substrate 102. In an embodiment, a vertical level of a lower surface of the word line cutting structure WLC may be lower than, for example, a vertical level of an upper surface of the source layer of the cell substrate 102. In some embodiments, the lower surface of the word line cutting structure WLC may be substantially coplanar with the lower surface of the source layer of the cell substrate 102.

In some embodiments, the word line cutting structure WLC may include an insulating material. For example, the word line cutting structure WLC may include at least one of silicon oxide, silicon nitride, or silicon oxynitride.

Each of the plurality of gate contacts GC may be formed in a contact hole GCH that corresponds respectively to the gate contact GC. For example, the plurality of gate contacts GC may be formed in a plurality of contact holes GCH, respectively. Each gate contact GC may include an insulating pattern 161 and a conductive pattern 162. The conductive pattern 162 may fill at least a portion of the contact hole GCH. The conductive pattern 162 may be in contact with a portion of the gate electrode 112 exposed through the contact hole GCH. The conductive pattern 162 may include a conductive material. The conductive pattern 162 may include, for example, at least one of tungsten (W), copper (Cu), aluminum (Al), or an alloy thereof.

The insulating pattern 161 may surround a side surface of the conductive pattern 162. The insulating pattern 161 may conformally extend along a sidewall of the conductive pattern 162. The insulating pattern 161 does not cover the portion of the gate electrode 112 exposed through the contact hole GCH. The insulating pattern 161 may include an insulating material. The insulating pattern 161 may include, for example, silicon oxide. However, embodiments of the present disclosure are not limited thereto.

The support pattern SP may be formed in the extension area EA. The support pattern SP may be formed around the gate contact GC. The support pattern SP may be a structure having a pillar shape (e.g., a cylindrical shape) extending in the third direction Z. The number and arrangement of the support patterns SP are only examples and are not limited to those shown, for example, in FIG. 3.

In some embodiments, the support pattern SP may include an insulating material, for example, silicon oxide, silicon nitride, and/or silicon oxynitride.

In some embodiments, the support pattern SP may be formed at a same level as a level of the channel structure CH. In this case, the support pattern SP may have a same structure as a structure of the channel structure CH and may include a same material as a material of the channel structure CH.

The cell interlayer insulating film 142 may be disposed on the stack structure SS. The cell interlayer insulating film 142 may be formed on the cell substrate 102 to cover the gate electrodes 112 and the mold insulating films 110. The cell interlayer insulating film 142 may include, for example, at least one of silicon oxide, silicon oxynitride, or a low-k material having a lower dielectric constant than a dielectric constant of silicon oxide. However, embodiments of the present disclosure are not limited thereto. Although not shown specifically, the cell interlayer insulating film 142 may include a plurality of insulating layers, and the number of layers of the cell interlayer insulating film 142 is not limited to that shown, for example, in FIG. 4.

The cell interlayer insulating film 142 of the cell array area CA may include a first contact pattern 181, a first conductive line 182, and a second contact pattern 185.

The first contact pattern 181 may be formed on the channel structure CH. The first contact pattern 181 may connect the channel pad 136 and the first conductive line 182 to each other. The first conductive line 182 may be electrically connected to the channel structure CH via the first contact pattern 181.

The first conductive line 182 may be disposed in the cell array area CA. The first conductive line 182 may extend in the second direction Y. Although not shown, the first conductive lines 182 may be spaced apart from each other in the first direction X and may extend in the second direction Y and in a parallel manner to each other. The first conductive line 182 may be electrically connected to the channel structures CH arranged in the second direction Y. The first conductive line 182 may be provided as the bit line BL (see FIG. 2).

The second contact pattern 185 may be formed on the stack structure SS of the cell array area CA. The second contact pattern 185 may be disposed between the first conductive line 182 and the first bonding pad 190. The second contact pattern 185 may connect the first conductive line 182 and the first bonding pad 190 to each other.

Each of the first contact pattern 181, the first conductive line 182, and the second contact pattern 185 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

The cell interlayer insulating film 142 of the extension area EA may further include a third contact pattern 183, a second conductive line 184, and a fourth contact pattern 186.

The third contact pattern 183 may be formed on the gate contact GC. The third contact pattern 183 may connect the gate contact GC and the second conductive line 184 to each other.

The second conductive line 184 may extend in the second direction Y and in the extension area EA. Although not shown, the second conductive lines 184 may be spaced apart from each other in the first direction X and may extend in the second direction Y and in a parallel manner to each other. The second conductive line 184 may be electrically connected to the gate contacts GC arranged in the second direction Y.

The fourth contact pattern 186 may be formed on the stack structure SS of the extension area EA. The fourth contact pattern 186 may be disposed between the second conductive line 184 and the first bonding pad 190. The fourth contact pattern 186 may connect the second conductive line 184 and the first bonding pad 190 to each other.

Each of the third contact pattern 183, the second conductive line 184, and the fourth contact pattern 186 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

A first bonding insulating layer 146 may be disposed on the cell interlayer insulating film 142. The first bonding pad 190 may be disposed in the first bonding insulating layer 146. The first bonding pad 190 may be electrically connected to the first contact pattern 181, the first conductive line 182, and the second contact pattern 185. The first bonding pad 190 may include a conductive material. In an embodiment, the first bonding pad 190 may include, for example, copper (Cu).

The peripheral circuit area PERI may include a first interlayer insulating film 242, a third interlayer insulating film 240, a first through-via 284, a first well area 1aW, a second well area 1bW, a first transistor PT1, a second transistor PT2, an isolation structure IST, a stopper structure CS, a guard area GB, a second interlayer insulating film 244, a second through-via 282A, a first contact 282B, a first wiring structure 280, and a second bonding pad 290.

A second bonding insulating layer 246 may be disposed on the memory cell area CELL. The second bonding pad 290 may be disposed in the second bonding insulating layer 246.

The second bonding insulating layer 246 may be disposed under the second interlayer insulating film 244. The second bonding pad 290 may be disposed in the second bonding insulating layer 246. The second bonding pad 290 may be electrically connected to the first wiring structure 280. The second bonding pad 290 may include a conductive material. The second bonding pad 290 may include, for example, copper (Cu).

The second bonding pad 290 may be in contact with the first bonding pad 190. The second bonding insulating layer 246 may contact the first bonding insulating layer 146. The first bonding insulating layer 146 may be formed between the first bonding pads 190, and the second bonding insulating layer 246 may be formed between the second bonding pads 290. Each of the first bonding insulating layer 146 and the second bonding insulating layer 246 may include silicon carbonitride. The second bonding insulating layer 246 may be in contact with the first bonding insulating layer 146.

As the first bonding pad 190 and the second bonding pad 290 are in contact with each other, the memory cell area CELL and the peripheral circuit area PERI may be bonded to each other. As the first bonding pad 190 and the second bonding pad 290 are bonded to each other, the memory cell area CELL may be electrically connected to the peripheral circuit area PERI.

The first interlayer insulating film 242 may be disposed on the memory cell area CELL. The first interlayer insulating film 242 may be disposed on the first well area 1aW and the second well area 1bW. The first interlayer insulating film 242 may be disposed between the second interlayer insulating film 244 and the third interlayer insulating film 240 in the third direction Z. The first interlayer insulating film 242 may include, for example, at least one of silicon oxide, silicon oxynitride, or a low-k material having a lower dielectric constant than a dielectric constant of silicon oxide. However, embodiments of the present disclosure are not limited thereto. Although not shown specifically, the first interlayer insulating film 242 may include a plurality of insulating layers. The number of layers of the first interlayer insulating film 242 is not limited to what is shown.

The first interlayer insulating film 242 may include at least a portion of the first through-via 284, and the first wiring line 285 connected to the first through-via 284. The first wiring line 285 may be connected to an input/output contact 288 to be described later. The first wiring line 285 may be electrically connected to an input/output pad 287 via the input/output contact 288.

Each of the first through-via 284 and the first wiring line 285 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

The third interlayer insulating film 240 may be disposed on the first interlayer insulating film 242 in the third direction Z. The third interlayer insulating film 240 may include the input/output pad 287 electrically connected to an external device that is external to the semiconductor device 10. The third interlayer insulating film 240 may include, for example, at least one of silicon oxide, silicon oxynitride, or a low-k material having a lower dielectric constant than a dielectric constant of silicon oxide. However, embodiments of the present disclosure are not limited thereto.

Each of the input/output pad 287 and the input/output contact 288 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

The first well area 1aW and the second well area 1bW may be disposed on the first interlayer insulating film 242. The first well area 1aW and the second well area 1bW may be alternately arranged with each other in the horizontal direction. As used herein, it may be understood that the first well area 1aW and the second well area 1bW are included in a well structure. The well structure may include a first surface 200_1 and a second surface 200_2 facing each other. That is, each of the first well area 1aW and the second well area 1bW may include the first and second surface 200_1 and 200_2 facing each other. The first surface 200_1 may be an area in contact with the first interlayer insulating film 242, and the second surface 200_2 may be an area in contact with the second interlayer insulating film 244. As used herein, the first surface 200_1 and the second surface 200_2 may also be referred to as a first area and a second area of the well structure, respectively.

The first transistor PT1 may be disposed in the first surface 200_1 of the first well area 1aW. For example, the first transistor PT1 may be disposed at the first surface of the first well area 1aW. The second transistor PT2 may be disposed in the first surface 200_1 of the second well area 1bW. For example, the second transistor PT2 may be disposed at the first surface of the second well area 1bW. The first transistor PT1 and the second transistor PT2 may be disposed on the first surface 200_1 of the well structure and in the second interlayer insulating film 244. For example, the first transistor PT1 and the second transistor PT2 may be disposed in the second interlayer insulating film 244 to contact the first surface of the first well area 1aW and the first surface of the second well area 1bW, respectively.

The first well area 1aW and the second well area 1bW may include different conductive materials. For example, the first well area 1aW may include a n-conductivity type material, and the second well area 1bW may include a p-conductivity type material. In this case, the first transistor PT1 may be PMOS, and the second transistor PT2 may be NMOS. However, embodiments are not limited thereto.

Each of the first and second transistors PT1 and PT2 may be an element for controlling an operation of the semiconductor memory device. For example, the first transistor PT1 may be electrically connected to the row decoder 33 (see FIG. 1), and the second transistor PT2 may be electrically connected to the page buffer 35 (see FIG. 1). However, embodiments are not limited thereto. The first and second transistors PT1 and PT2 may be electrically connected to various circuits of the peripheral circuit (e.g., the peripheral circuit 30 of FIG. 1).

In the first direction X and/or the second direction Y, the isolation structure IST may be disposed between the first well area 1aW and the second well area 1bW (best seen in FIG. 5). For example, the isolation structure IST may be disposed between the first well area 1aW and the second well area 1bW in the first direction X. The isolation structure IST may extend in the third direction Z while being disposed between the first well area 1aW and the second well area 1bW in the first direction X. The isolation structure IST may extend through the well structure in the third direction Z.

In the third direction Z, the isolation structure IST may be disposed between the first interlayer insulating film 242 and the second interlayer insulating film 244. A width of the isolation structure IST in each of the first direction X and/or the second direction Y may decrease as the isolation structure IST extends from the second interlayer insulating film 244 toward the first interlayer insulating film 242. However, embodiments of the present disclosure are not limited thereto.

The isolation structure IST may electrically isolate the first well area 1aW and the second well area 1bW from each other. The isolation structure IST may include an insulating material. The isolation structure IST may include, for example, at least one of silicon oxide, silicon oxynitride, or a low dielectric constant (low-k) material having a dielectric constant lower than a dielectric constant of silicon oxide. However, embodiments of the present disclosure are not limited thereto.

Referring to FIGS. 4 and 5, the stopper structure CS may be disposed on the isolation structure IST. The stopper structure CS may be disposed in the second interlayer insulating film 244 and may be disposed on the first surface 200_1 of the well structure and may vertically overlap the isolation structure IST in the third direction Z. For example, the stopper structure CS may be disposed in the second interlayer insulating film 244 and may contact the first surface of the well structure and may vertically overlap the isolation structure IST in the third direction Z.

In the stopper structure CS, the first through-via 284 and the second through-via 282A may at least partially overlap each other in the third direction Z. Lengths in the third direction Z of the first through-via 284 and the second through-via 282A may be different from each other. In an embodiment, the length in the third direction Z of the first through-via 284 may be greater than the length in the third direction Z of the second through-via 282A. A width in the horizontal direction of each of the first through-via 284 and the second through-via 282A may decrease as each of the first through-via 284 and the second through-via 282A extends toward the stopper structure CS. For example, the width in the horizontal direction of the first through-via 284 may decrease as the first through-via 284 extends from the first wiring line 285 toward the stopper structure CS, and the width in the horizontal direction of the second through-via 282A may decrease as the second through-via 282A extends from the second wiring line 281 toward the stopper structure CS, as shown in, for example, FIG. 5.

The first through-via 284 and the second through-via 282A may be spaced apart from each other while being disposed in the stopper structure CS. A vertical level of one end in the third direction Z of the first through-via 284 in the stopper structure CS may be different from a vertical level of one end in the third direction Z of the second through-via 282 A in the stopper structure CS.

The stopper structure CS may include a conductive material. As used herein, the stopper structure CS may be referred to as a conductive structure. The stopper structure CS may include a conductive material such as a metal material and/or a doped semiconductor material. For example, the stopper structure CS may include at least one of a n-conductive material, a p-conductive material, polysilicon (poly Si), silicon germanium (SiGe), tungsten (W), titanium nitride (TiN), tantalum nitride (TaN), copper (Cu), aluminum (Al), or molybdenum (Mo). However, embodiments of the present disclosure are not limited thereto.

In an embodiment, the stopper structure CS may be formed in a same process as a process in which the first transistor PT1 and the second transistor PT2 are formed. In this case, the stopper structure CS may include a same material as a material of each of the first transistor PT1 and the second transistor PT2. The detailed structure and material of the stopper structure CS will be described later.

Unlike the first and second transistors PT1 and PT2, the stopper structure CS may not function as an element for controlling the operation of the semiconductor memory device.

The guard area GB may be disposed in each of the first well area 1aW and the second well area 1bW and in the first surface 200_1 of the first well area 1aW and the second well area 1bW. For example, the guard area GB may be disposed in each of the first well area 1aW and the second well area 1bW and may contact the first surface of the first well area 1aW and the second well area 1bW. In the cross-sectional view as shown, for example in FIG. 4, the guard area GB may be disposed on each of both opposing sides of the first transistor PT1 and in the first well area 1aW and may be disposed each of both opposing sides of the second transistor PT2 and in the second well area 1bW.

The guard area GB may be electrically connected to at least one of the first well area 1aW or the second well area 1bW. For example, when the first well area 1aW includes a n-conductivity material, the guard area GB in the first well area 1aW may include a n-conductivity material. When the second well area 1bW includes a p-conductivity material, the guard area GB in the second well area 1bW may include a p-conductivity material.

As used herein, the guard area GB may be referred to as a bias area. The guard area GB may be connected to a wiring (not shown) that provides a ground voltage to each of the transistors PT1 and PT2 to provide a bias voltage to at least one of the first well area 1aW or the second well area 1bW. Although not shown specifically, in this case, the wiring (not shown) may be disposed in the second interlayer insulating film 244 and on the first surface 200_1 of the well structure.

The first through-via 284 may extend through the isolation structure IST and extend in the third direction Z. The first through-via 284 may extend in the third direction Z and in the first interlayer insulating film 242 so as to contact the stopper structure CS. At least a portion of the first through-via 284 may be disposed in the stopper structure CS.

The second interlayer insulating film 244 may be disposed on the memory cell area CELL. The second interlayer insulating film 244 may be disposed between the first interlayer insulating film 242 and the memory cell area CELL in the third direction Z. The second interlayer insulating film 244 may be disposed between the well structure and the memory cell area CELL in the third direction Z. The second interlayer insulating film 244 may include, for example, at least one of silicon oxide, silicon oxynitride, or a low-k material having a lower dielectric constant than a dielectric constant of silicon oxide. However, embodiments of the present disclosure are not limited thereto. Although not shown specifically, the second interlayer insulating film 244 may include a plurality of insulating layers, and the number of layers of the second interlayer insulating film 244 is not limited to that shown.

The second interlayer insulating film 244 may receive therein at least a portion of the second through-via 282A, the second wiring line 281 connected to the second through-via 282A, and the first contact 282B connected to the second wiring line 281.

The second through-via 282A may be disposed on the first through-via 284. The second through-via 282A may extend in the third direction Z and in the second interlayer insulating film 244 so as to contact the stopper structure CS. At least a portion of the second through-via 282A may be disposed in the stopper structure CS.

The second wiring line 281 may connect the second through-via 282A and the first contact 282B to each other in the horizontal direction. The first contact 282B may extend in the second interlayer insulating film 244 and in the third direction Z so as to be connected to the guard area GB.

The stopper structure CS may be electrically connected to the guard area GB via the second through-via 282A, the second wiring line 281, and the first contact 282B. Each of the first through-via 284 and the second through-via 282A may be electrically connected to the guard area GB.

Each of the first through-via 284, the second through-via 282A, the second wiring line 281, and the first contact 282B may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

The second interlayer insulating film 244 may further include the first wiring structure 280. The first wiring structure 280 may be disposed between the second wiring line 281 and the second bonding pad 290. The first wiring structure 280 may include a plurality of wirings and a plurality of vias for electrically connecting the second wiring line 281 and the second bonding pad 290 to each other. The first wiring structure 280 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto. The number, the number of layers, and the positional relationship of the plurality of wirings and the plurality of vias included in the first wiring structure 280 are not limited to those shown, for example, in FIG. 4.

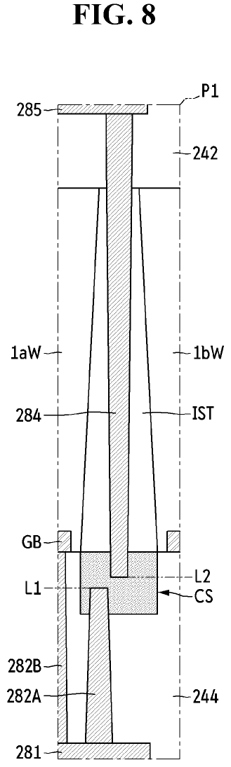

FIGS. 8 to 12 are diagrams corresponding to the enlarged view of FIG. 5 for illustrating a semiconductor memory device according to some embodiments. For convenience of description, contents duplicative with contents described above with reference to FIGS. 1 to 7 will be briefly described or the descriptions thereof will be omitted for conciseness.

Referring to FIG. 8, in some embodiments, in the stopper structure CS, the first through-via 284 and the second through-via 282A may not overlap each other in the third direction Z. In the stopper structure CS of FIG. 8, a vertical level L2 of one end in the third direction Z of the first through-via 284 may be higher than or equal to a vertical level L1 of one end in the third direction Z of the second through-via 282A.

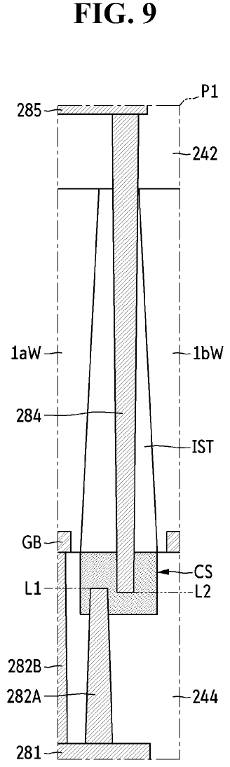

Referring to FIG. 9, in some embodiments, in the stopper structure CS, the vertical level L2 of one end in the third direction Z of the first through-via 284 may be lower than or equal to a vertical level L1 of one end in the third direction Z of the second through-via 282A.

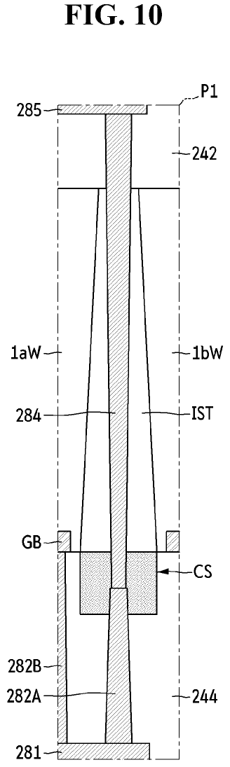

Referring to FIG. 10, in some embodiments, in the stopper structure CS, the first through-via 284 and the second through-via 282A may be in contact with each other. In the stopper structure CS of FIG. 10, the vertical level of one end in the third direction Z of the first through-via 284 may be equal to the vertical level of one end in the third direction Z of the second through-via 282A.

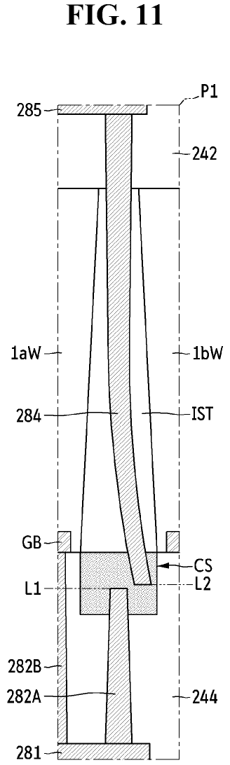

Referring to FIG. 11, in some embodiments, in the stopper structure CS, the first through-via 284 may be bent toward one side. In the stopper structure CS of FIG. 11, the first through-via 284 may have a curved surface. In the stopper structure CS of FIG. 11, the vertical level L2 of one end in the third direction Z of the first through-via 284 may be equal to or higher than the vertical level L1 of one end in the third direction Z of the second through-via 282A.

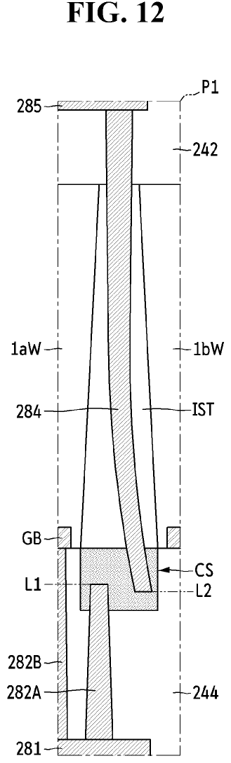

Referring to FIG. 12, in some embodiments, in the stopper structure CS, the first through-via 284 may be bent toward one side. In the stopper structure CS of FIG. 12, the first through-via 284 may have a curved surface. In the stopper structure CS of FIG. 12, the vertical level L2 of one end in the third direction Z of the first through-via 284 may be equal to or lower than the vertical level L1 of one end in the third direction Z of the second through-via 282A.

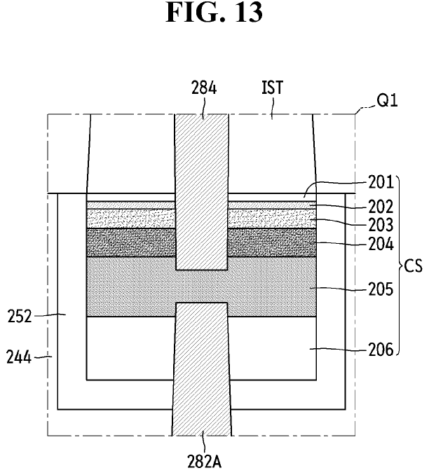

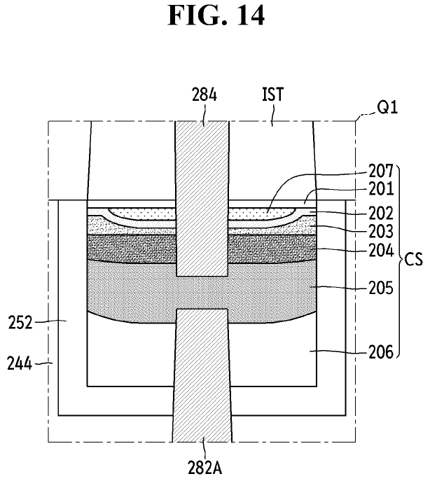

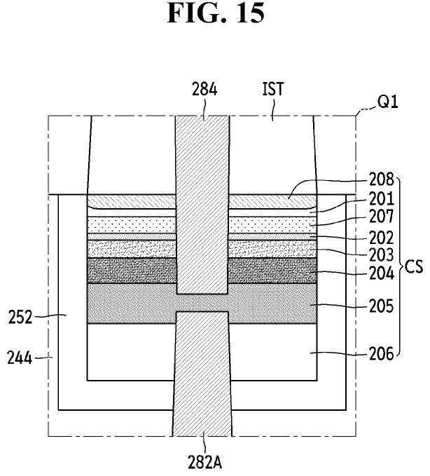

FIG. 13 is an enlarged view of an area Q1 of FIG. 5. FIGS. 14 and 15 are diagrams corresponding to the enlarged view of FIG. 13 for illustrating a semiconductor memory device according to some embodiments. For convenience of description, contents duplicative with contents described above with reference to FIGS. 1 to 12 will be briefly described or the descriptions thereof will be omitted for conciseness.

Referring to FIG. 13, the stopper structure CS may include the same structure as that of the NMOS transistor. The stopper structure CS may include a gate insulating film 201, a first gate conductive layer 202, a second gate conductive layer 203, a third gate conductive layer 204, a fourth gate conductive layer 205, and a cap layer 206, which are sequentially stacked on the isolation structure IST.

For example, in an embodiment, each of one end of the first through-via 284 and one end of the second through-via 282A may be disposed in the fourth gate conductive layer 205 of the stopper structure CS. However, embodiments of the present disclosure are not limited thereto.

For example, the gate insulating film 201 may include a high-k material. The high-k material may refer to a dielectric material having a dielectric constant higher than a dielectric constant of the silicon oxide SiO₂. The high dielectric constant material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). However, embodiments of the present disclosure are not limited thereto.

For example, the first gate conductive layer 202 may include a metal material. For example, the first gate conductive layer 202 may include at least one of titanium (Ti), titanium nitride (TiN), tantalum (Ta), or tantalum nitride (TaN).

For example, the second gate conductive layer 203 may include a metal material. For example, the second gate conductive layer 203 may include at least one of titanium (Ti), titanium nitride (TiN), tantalum (Ta), or tantalum nitride (TaN). A thickness of the second gate conductive layer 203 may be greater than a thickness of the first gate conductive layer 202. However, embodiments of the present disclosure are not limited thereto.

For example, the third gate conductive layer 204 may include a conductive semiconductor material such as polysilicon. A thickness of the third gate conductive layer 204 may be greater than a thickness of each of the first gate conductive layer 202 and the second gate conductive layer 203. However, embodiments of the present disclosure are not limited thereto.

For example, the fourth gate conductive layer 205 may include at least one of, for example, tungsten (W), tungsten nitride (WN), ruthenium (Ru), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V). A thickness of the fourth gate conductive layer 205 may be greater than a thickness of the third gate conductive layer 204. However, embodiments of the present disclosure are not limited thereto.

For example, the cap layer 206 may include silicon nitride (SiN), and a thickness of the cap layer 206 may be greater than a thickness of the fourth gate conductive layer 205. However, embodiments of the present disclosure are not limited thereto.

A capping film 252 may cover at least a portion of a surface of the stopper structure CS. The capping film 252 may be disposed on a sidewall and a at least a portion of an upper surface of each of the first transistor PT1, the second transistor PT2, and the stopper structure CS. The capping film 252 may include, for example, silicon nitride. However, embodiments of the present disclosure are not limited thereto.

Referring to FIG. 14, the stopper structure CS may be formed in a process for forming a NMOS transistor or a PMOS transistor, and may have a structure different from that of each of the NMOS transistor or the PMOS transistor. The stopper structure CS may include the gate insulating film 201, a fifth gate conductive layer 207, the first gate conductive layer 202, the second gate conductive layer 203, the third gate conductive layer 204, the fourth gate conductive layer 205, and the cap layer 206, which are sequentially stacked on the isolation structure IST.

For example, the fifth gate conductive layer 207 may include a metal material. For example, the fifth gate conductive layer 207 may include at least one of titanium (Ti), titanium nitride (TiN), tantalum (Ta), or tantalum nitride (TaN).

Referring to FIG. 15, the stopper structure CS may include the same structure as a structure of the PMOS transistor. The stopper structure CS may include a semiconductor material layer 208, the gate insulating film 201, the fifth gate conductive layer 207, the first gate conductive layer 202, the second gate conductive layer 203, the third gate conductive layer 204, the fourth gate conductive layer 205, and the cap layer 206, which are sequentially stacked on the isolation structure IST. For example, the semiconductor material layer 208 may include SiGe.

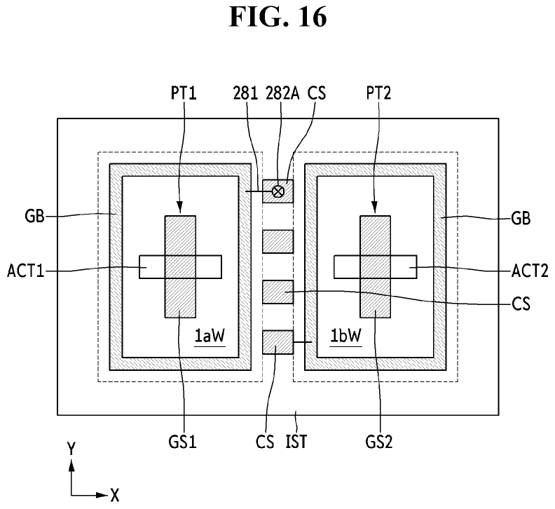

FIGS. 16 to 18 are example layout diagrams for illustrating a semiconductor memory device according to some embodiments. For convenience of description, contents duplicative with contents described above with reference to FIGS. 1 to 15 will be briefly described or the descriptions thereof will be omitted for conciseness. For reference, FIGS. 16 to 18 are schematic layout diagrams for illustrating the semiconductor memory device as described with reference to FIG. 4.

Referring to FIG. 16, the first transistor PT1 may include a first gate structure GS1 and a first active area ACT1. The second transistor PT2 may include a second gate structure GS2 and a second active area ACT2. Each of the first gate structure GS1 and the second gate structure GS2 may extend in the second direction Y, and each of the first active area ACT1 and the second active area ACT2 may extend in the first direction X.

In a plan view, the guard area GB may extend in a ring shape while being disposed in each of the first well area 1aW or the second well area 1bW. In a plan view, a plurality of stopper structures CS may be disposed between the first and second well areas 1aW and 1bW. As used herein, the plan view may denote a top view of a semiconductor memory device according to some embodiments.

The stopper structure CS may be electrically connected to the guard area GB via the second through-via 282A and the second wiring line 281 connected to the second through-via 282A.

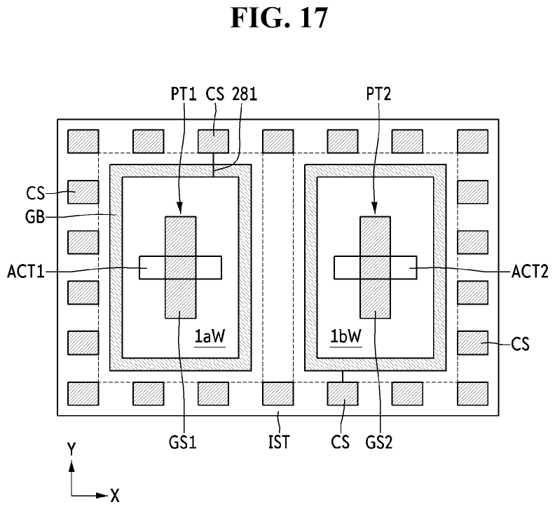

Referring to FIG. 17, in a plan view, a plurality of stopper structures CS may be disposed around the first and second well areas 1aW and 1bW. In a plan view, a plurality of stopper structures CS may be spaced apart from each other and may be arranged in a form surrounding the first and second well areas 1aW and 1bW. The stopper structure CS may be electrically connected to the guard area GB via a second wiring line 281 extending in the second direction Y.

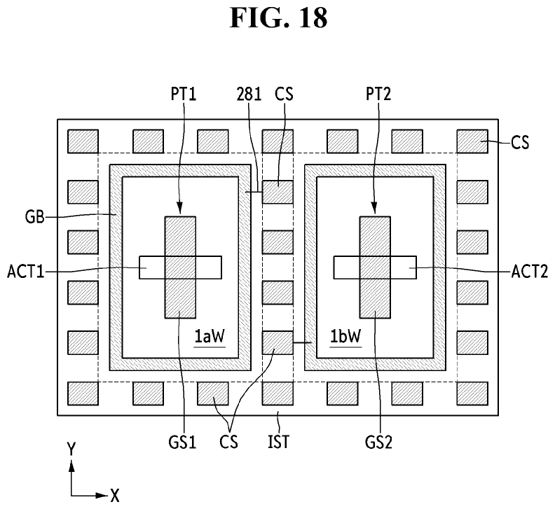

Referring to FIG. 18, in a plan view, a plurality of stopper structures CS may be spaced apart from each other and may be disposed between the first and second well areas 1aW and 1bW and around the first and second well areas 1aW and 1bW.

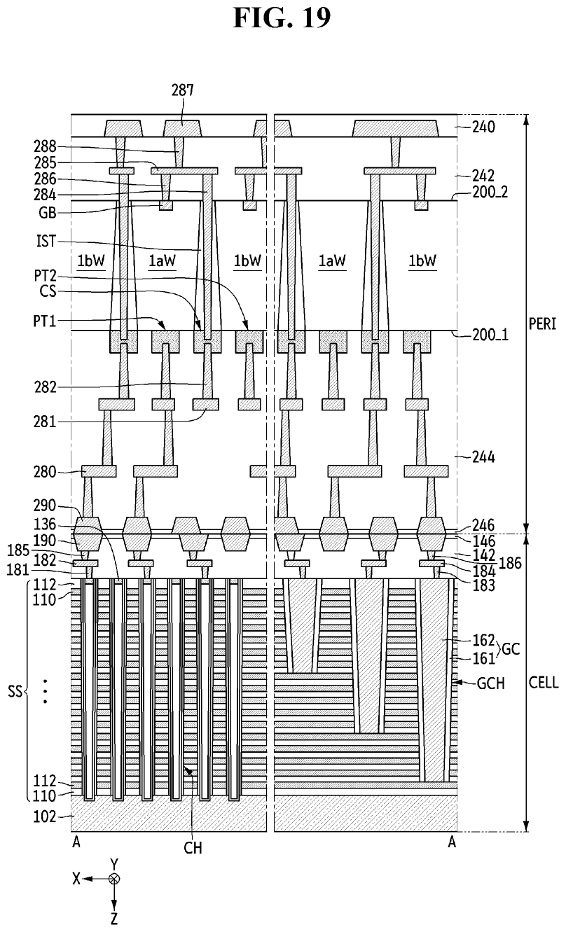

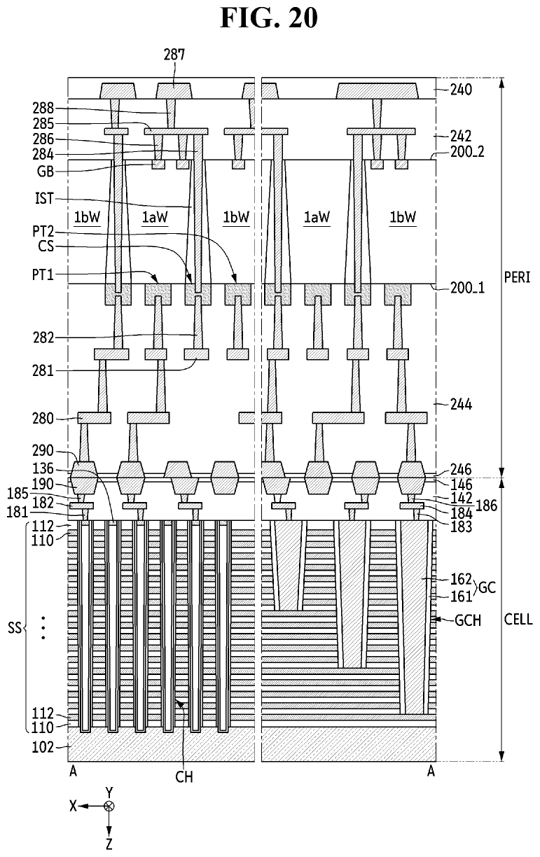

FIGS. 19 and 20 are cross-sectional views illustrating a semiconductor memory device according to some embodiments. For convenience of description, contents duplicative with contents described above with reference to FIGS. 1 to 18 will be briefly described or the descriptions thereof will be omitted for conciseness.

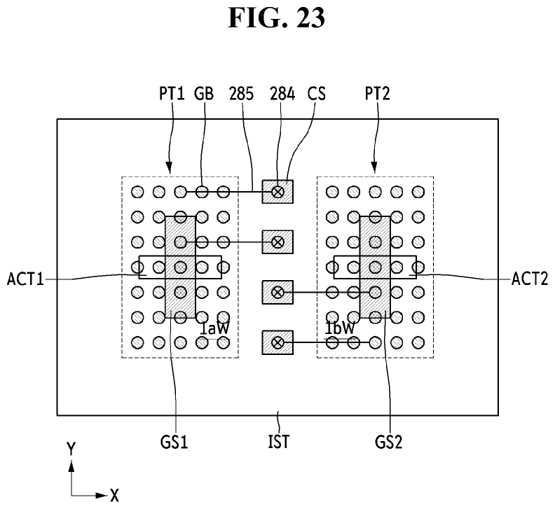

Referring to FIG. 19, the guard area GB may be disposed in the first well area 1aW and the second well area 1bW and in the second surface 200_2 of each of the first well area 1aW and the second well area 1bW. For example, the guard area GB may be disposed in the first well area 1aW and the second well area 1bW to contact the second surface of each of the first well area 1aW and the second well area 1bW. As will be described below in FIG. 23, in a plan view, a plurality of guard areas GB may be arranged in a matrix form while being disposed in each of the first well area 1aW and the second well area 1bW.

The guard area GB may be electrically connected to at least one of the first well area 1aW or the second well area 1bW. For example, when the first well area 1aW includes a n-conductivity material, the guard area GB in the first well area 1aW may include a n-conductivity material. When the second well area 1bW includes a p-conductivity material, the guard area GB in the second well area 1bW may include a p-conductivity material.

The guard area GB may be referred to as a bias area. The guard area GB may be connected to a wiring (not shown) that provides a ground voltage to each of the transistors PT1 and PT2 to provide the bias voltage to at least one of the first and second well areas 1aW and 1bW. Although not shown specifically, in this case, the wiring (not shown) may be disposed in the first interlayer insulating film 242 and on the second surface 200_2 of the well structure.

The first interlayer insulating film 242 may further include the second contact 286 connected to the first wiring line 285. The second contact 286 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

Although not specifically illustrated, a plurality of the second contacts 286 may be spaced apart from the first wiring line 285 and may be disposed on the second surface 200_2.

The stopper structure CS may be electrically connected to the guard area GB via the first through-via 284, the first wiring line 285 connected to the first through-via 284, and the second contact 286 connected to the first wiring line 285 and extending in the third direction Z.

Referring to FIG. 20, a plurality of the second contacts 286 connected to the first wiring line 285 may be disposed on the second surface 200_2. In a plan view, a plurality of guard areas GB may be arranged in a matrix form while being disposed in each of the first well area 1aW and the second well area 1bW. The plurality of guard areas GB may be connected to the first wiring line 285 through the plurality of second contacts 286, respectively.

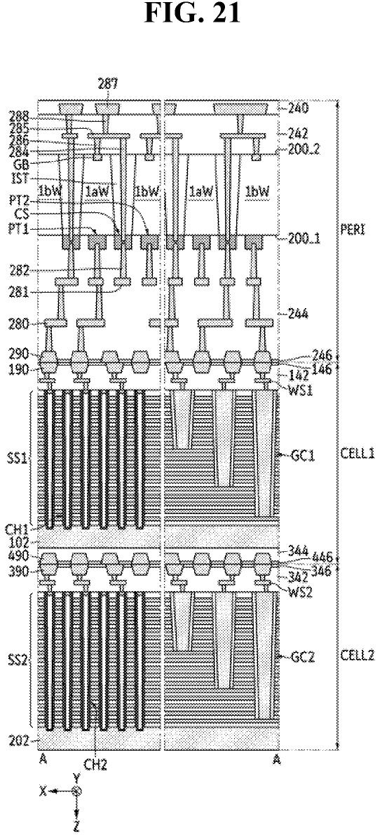

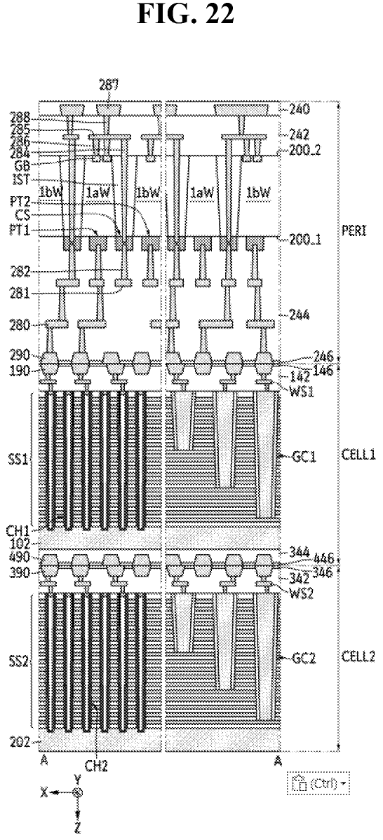

FIGS. 21 and 22 are cross-sectional views illustrating a semiconductor memory device according to some embodiments. For convenience of description, contents duplicative with contents described above with reference to FIGS. 1 to 20 will be briefly described or the descriptions thereof will be omitted for conciseness.

Referring to FIG. 21, the semiconductor memory device according to some embodiments may include a first memory cell area CELL1, a second memory cell area CELL2, and a peripheral circuit area PERI. In FIG. 21, an example in which only two memory cell areas CELL1 and CELL2 are included in the semiconductor memory device is illustrated. However, embodiments of the present disclosure are not limited thereto. Unlike the illustrated example in FIG. 21, the semiconductor memory device may include memory cell areas stacked in two or more layers.

The first memory cell area CELL1 may include a first stack structure SS1, a first channel structure CH1, a first gate contact GC1, the first cell interlayer insulating film 142, a first cell wiring structure WS1, the first bonding insulating layer 146, and the first bonding pad 190.

The first stack structure SS1 may include a plurality of gate electrodes and a plurality of mold insulating films which may be stacked on the first cell substrate 102. The description of the cell substrate 102 as set forth above with reference to FIGS. 4 and 19 may be equally applied to the material of the first cell substrate 102 in FIG. 21. The descriptions of the plurality of gate electrodes 112 and the plurality of mold insulating films 110 as set forth above with reference to FIGS. 4 and 19 may be equally applied to the structures and materials of the plurality of gate electrodes and the plurality of mold insulating films in FIG. 21.

The first channel structure CH1 may be disposed on the cell array area (e.g. the cell array area CA of FIG. 3). Each of the plurality of first channel structures CH1 may extend in the third direction Z to extend through the first stack structure SS1. The description of the channel structure CH as set forth above with reference to FIGS. 4 and 19 may be equally applied to the structure and material of the first channel structure CH1 in FIG. 21.

The first gate contact GC1 may be disposed on the extension area EA (see FIG. 3). Each of the plurality of first gate contacts GC1 may extend in the third direction Z to at least partially extend through the first stack structure SS1. The description of the gate contact GC as set forth above with reference to FIGS. 4 and 19 may be equally applied to the structure and material of the first gate contact GC1 in FIG. 21.

The first cell interlayer insulating film 142 may be disposed on the first stack structure SS1. The first cell interlayer insulating film 142 may be formed on the first cell substrate 102 so as to cover the first stack structure SS1. The description of the cell interlayer insulating film 142 as set forth above with reference to FIGS. 4 and 19 may be equally applied to the structure and material of the first cell interlayer insulating film 142 in FIG. 21.

The first cell wiring structure WS1 may be disposed in the first cell interlayer insulating film 142. The first cell wiring structure WS1 may include a plurality of wiring lines and a plurality of vias electrically connected to the first channel structure CH1, and a plurality of wiring lines and a plurality of vias electrically connected to the first gate contact GC1.

The first bonding insulating layer 146 may be disposed on the first cell interlayer insulating film 142. The first bonding pad 190 may be disposed in the first bonding insulating layer 146 and the first cell interlayer insulating film 142. The description of the first bonding insulating layer 146 and the first bonding pad 190 as set forth above with reference to FIGS. 4 and 19 may be equally applied to the structure and material of the first bonding insulating layer 146 and the first bonding pad 190 in FIG. 21.

The first bonding insulating layer 146 and the first bonding pad 190 may be directly bonded to the second bonding insulating layer 246 and the second bonding pad 290 of the peripheral circuit area PERI, respectively.

The first memory cell area CELL1 may further include a third cell interlayer insulating film 344, a fourth bonding insulating layer 446, and a fourth bonding pad 490. The third cell interlayer insulating film 344 may be disposed between the first cell substrate 102 and the fourth bonding insulating layer 446. Although not shown, a plurality of wirings and a plurality of vias electrically connected to the first cell substrate 102 of the first memory cell area CELL1 may be disposed in the third cell interlayer insulating film 344. The description of the cell interlayer insulating film 142 as set forth above with reference to FIGS. 4 and 19 may be equally applied to the material of the third cell interlayer insulating film 344 in FIG. 21.

The fourth bonding insulating layer 446 and the fourth bonding pad 490 may be disposed under the first cell substrate 102. The description of the first bonding insulating layer 146 and the first bonding pad 190 as set forth above with reference to FIGS. 4 and 19 may be equally applied to the materials of the fourth bonding insulating layer 446 and the fourth bonding pad 490 in FIG. 21.

The second memory cell area CELL2 may include a second stack structure SS2, a second channel structure CH2, a second gate contact GC2, a second cell interlayer insulating film 342, a second cell wiring structure WS2, a third bonding insulating layer 346, and a third bonding pad 390.

The second stack structure SS2 may include a plurality of gate electrodes and a plurality of mold insulating films which may be stacked on the second cell substrate 202. The description of the cell substrate 102 as set forth above with reference to FIGS. 4 and 19 may be equally applied to the material of the second cell substrate 202 in FIG. 21. The descriptions of the plurality of gate electrodes 112 and the plurality of mold insulating films 110 as set forth above with reference to FIGS. 4 and 19 may be equally applied to the structures and materials of the plurality of gate electrodes and the plurality of mold insulating films in FIG. 21.

The second channel structure CH2 may be disposed on the cell array area (CA of FIG. 3). Each of the plurality of second channel structures CH2 may extend in the third direction Z to extend through the second stack structure SS2. The description of the channel structure CH as set forth above with reference to FIGS. 4 and 19 may be equally applied to the structure and material of the second channel structure CH 2 in FIG. 21.

The second gate contact GC2 may be disposed on the extension area EA (see FIG. 3). The plurality of second gate contacts GC2 may each extend in the third direction Z to at least partially extend through the second stack structure SS2. The description of the gate contact GC as set forth above with reference to FIGS. 4 and 19 may be equally applied to the structure and material of the second gate contact GC2 in FIG. 21.

The second cell interlayer insulating film 342 may be disposed on the second stack structure SS2. The second cell interlayer insulating film 342 may be formed on the second cell substrate 202 so as to cover the second stack structure SS2. The description of the cell interlayer insulating film 142 as set forth above with reference to FIGS. 4 and 19 may be equally applied to the structure and material of the second cell interlayer insulating film 342 in FIG. 21.

The second cell wiring structure WS2 may be disposed in the second cell interlayer insulating film 342. The second cell wiring structure WS2 may include a plurality of wiring lines and a plurality of vias electrically connected to the second channel structure CH 2, and a plurality of wiring lines and a plurality of vias electrically connected to the second gate contact GC2.

The third bonding insulating layer 346 may be disposed on the second cell interlayer insulating film 342. The third bonding pad 390 may be disposed in the third bonding insulating layer 346 and the second cell interlayer insulating film 342. The description of the first bonding insulating layer 146 and the first bonding pad 190 as set forth above with reference to FIGS. 4 and 19 may be equally applied to the structure and material of the third bonding insulating layer 346 and the third bonding pad 390 in FIG. 21.

The third bonding insulating layer 346 and the third bonding pad 390 may be directly bonded to the fourth bonding insulating layer 446 and the fourth bonding pad 490 of the first memory cell area CELL1, respectively.

A width of the isolation structure IST may decrease as the isolation structure IST extends toward the stopper structure CS. The width of the first well area 1aW may increase as the first well area 1aW extends toward the stopper structure CS, and the width of the second well area 1bW may increase as the second well area 1bW extends toward the stopper structure CS.

Referring to FIG. 22, a plurality of the second contacts 286 connected to the first wiring lines 285 may be disposed on the second surface 200_2. In a plan view, a plurality of guard areas GB may be arranged in a matrix form while being disposed in each of the first well area 1aW and the second well area 1bW. The plurality of guard areas GB may be connected to the first wiring line 285 via the plurality of second contacts 286, respectively.

FIGS. 23 to 25 are example layout diagrams for illustrating a semiconductor memory device according to some embodiments. For convenience of description, contents duplicative with contents described above with reference to FIGS. 1 to 20 will be briefly described or the descriptions thereof will be omitted for conciseness.

Referring to FIG. 23, in a plan view, a plurality of stopper structures CS may be disposed between the first and second well areas 1aW and 1bW. The stopper structure CS may be electrically connected to the guard areas GB arranged in a matrix form and spaced apart from each other via the first wiring line 285 connected to the first through-via 284. The same bias voltage may be provided to the guard areas GB and the stopper structure CS connected to each other via the first wiring line 285. The number and positions of the guard areas GB connected to the stopper structure CS via the first wiring line 285 are not limited to those shown, for example, in FIG. 23. The number and positions of the guard areas GB arranged so as to be spaced apart from each other in each of the first and second well areas 1aW and 1bW are not limited to those shown, for example, in FIG. 23.

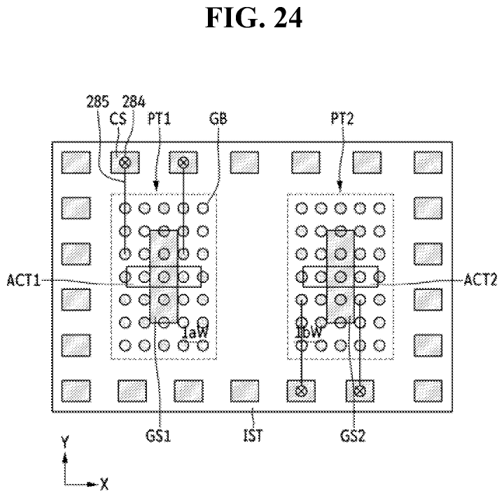

Referring to FIG. 24, in a plan view, a plurality of stopper structures CS may be arranged around the first and second well areas 1aW and 1bW.

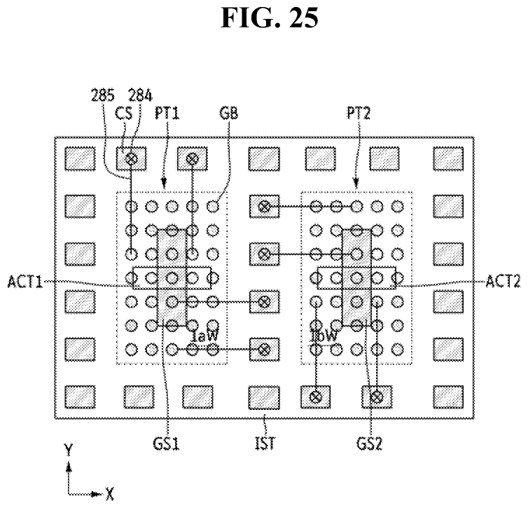

Referring to FIG. 25, in a plan view, a plurality of stopper structures CS may be spaced apart from each other while being arranged between the first and second well areas 1aW and 1bW and around the first and second well areas 1aW and 1bW.

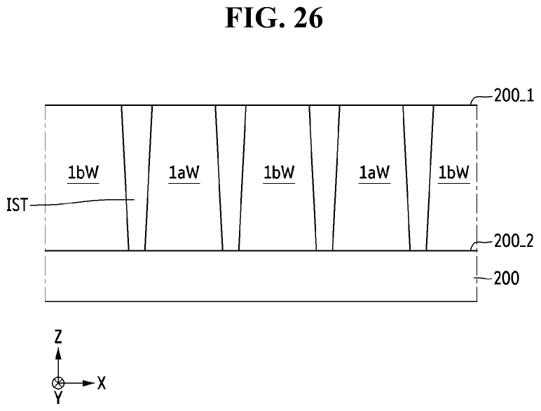

FIGS. 26 to 35 are diagrams of intermediate structures corresponding to intermediate steps of a method for manufacturing a semiconductor memory device according to some embodiments. For convenience of description, contents duplicative with contents described above with reference to FIGS. 1 to 25 will be briefly described or the descriptions thereof will be omitted for conciseness.

Referring to FIG. 26, a base substrate 200 is provided. The base substrate 200 may include a semiconductor material, for example, silicon (Si). In some embodiments, the base substrate 200 may include a semiconductor element material such as germanium (Ge) or a compound semiconductor material such as silicon carbide (SiC), gallium arsenide (GaAs), indium arsenide (InAs), and/or indium phosphide (InP). The base substrate 200 may include a conductive area, for example, an impurity-doped well or an impurity-doped structure. In some embodiments, the base substrate 200 may include a p-conductivity material.

The base substrate 200 may include a first surface 200_1 and a second surface 200_2 facing each other. As described above, the first surface 200_1 and the second surface 200_2 may be alternatively referred to as a first surface and a second surface, respectively. The first and second well areas 1aW and 1bW may be formed from the second surface 200_2 to the first surface 200_1 of the base substrate 200. The first and second well areas 1aW and 1bW may be alternately arranged with each other while being disposed in the base substrate 200. The first well area 1aW may include a n-conductivity material, and the second well area 1bW may include a p-conductivity material. The second well area 1bW may be an area doped with a p-type material having a relatively higher concentration than a concentration of the p-type material in the base substrate 200.

The isolation structure IST may be formed between the first and second well areas 1aW and 1bW. For example, the width of the isolation structure IST in the first direction X may decrease as the isolation structure extends toward the base substrate 200 (i.e., from the first surface 200_1 toward the second surface 200_2). The isolation structure IST may include, for example, an insulating material such as silicon oxide. The isolation structure IST may be formed by filling a trench extending from the first surface 200_ 1 to the second surface 200_ 2 with the insulating material.

Although not shown specifically, an element isolation film (not shown) may be formed on each of both opposing sides of the isolation structure IST. For example, the element isolation film may have a shallow trench isolation (STI) structure.

Although not shown specifically, a first guard area (e.g., the guard area GB of FIG. 4) for providing a first bias voltage to at least one of the first well area 1aW or the second well area 1bW may be formed on the first surface 200_1 of the base substrate 200. In this case, the stopper structure CS of FIG. 4 may be electrically connected to the first guard area GB of FIG. 4 via the first contact 282B of FIG. 4 on the first surface 200_1.

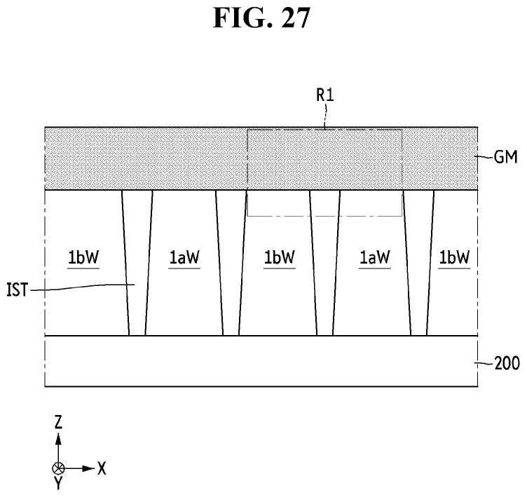

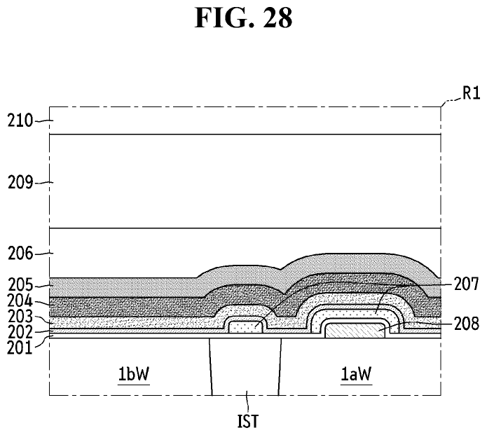

FIG. 28 is an enlarged view of an area R1 of FIG. 27.

Referring to FIGS. 27 and 28, a gate material layer GM may be formed on the first and second well areas 1aW and 1bW and the isolation structure IST. The gate material layer GM may be formed such that respective structures of portions thereof respectively disposed on the first well area 1aW, the isolation structure IST, and the second well area IbW are different from each other.

When the second well area 1bW includes a p-conductivity material, an NMOS transistor may be formed on the second well area 1bW.

The portion of the gate material layer GM on the second well area 1bW may include the gate insulating film 201, the first gate conductive layer 202, the second gate conductive layer 203, the third gate conductive layer 204, the fourth gate conductive layer 205, and the cap layer 206. The descriptions of the gate insulating film 201, the first gate conductive layer 202, the second gate conductive layer 203, the third gate conductive layer 204, the fourth gate conductive layer 205, and the cap layer 206 as set forth above with reference to FIG. 13 may be equally applied to the materials of the gate insulating film 201, the first gate conductive layer 202, the second gate conductive layer 203, the third gate conductive layer 204, the fourth gate conductive layer 205, and the cap layer 206 on the second well area 1bW in FIGS. 27 and 28.

When the first well area 1aW includes a n-conductivity material, an PMOS transistor may be formed on the first well area 1aW.

The portion of the gate material layer GM on the first well area 1aW may include the semiconductor material layer 208, the gate insulating film 201, the fifth gate conductive layer 207, the first gate conductive layer 202, the second gate conductive layer 203, the third gate conductive layer 204, the fourth gate conductive layer 205, and the cap layer 206. For example, the semiconductor material layer 208 may include SiGe. The descriptions of the semiconductor material layer 208, the gate insulating film 201, the fifth gate conductive layer 207, the first gate conductive layer 202, the second gate conductive layer 203, the third gate conductive layer 204, the fourth gate conductive layer 205, and the cap layer 206 as set forth above with reference to FIG. 15 may be applied equally and respectively to the semiconductor material layer 208, the gate insulating film 201, the fifth gate conductive layer 207, the first gate conductive layer 202, the second gate conductive layer 203, the third gate conductive layer 204, the fourth gate conductive layer 205, and the cap layer 206 on the first well area 1aW in FIGS. 27-28.

The portion of the gate material layer GM on the isolation structure IST may be formed in a process for forming the portion of the gate material layer of the NMOS transistor or the PMOS transistor, and may have a structure different from the structure of the portion of the gate material layer of the NMOS transistor or the PMOS transistor. The portion of the gate material layer GM on the isolation structure IST may include the gate insulating film 201, the fifth gate conductive layer 207, the first gate conductive layer 202, the second gate conductive layer 203, the third gate conductive layer 204, the fourth gate conductive layer 205, and the cap layer 206. The descriptions of the gate insulating film 201, the fifth gate conductive layer 207, the first gate conductive layer 202, the second gate conductive layer 203, the third gate conductive layer 204, the fourth gate conductive layer 205, and the cap layer 206 as set forth above with reference to FIG. 14 may be applied equally and respectively to the gate insulating film 201, the fifth gate conductive layer 207, the first gate conductive layer 202, the second gate conductive layer 203, the third gate conductive layer 204, the fourth gate conductive layer 205, and the cap layer 206 on the isolation structure IST in FIGS. 27-28.

The semiconductor material layer 208 may be selectively formed on the first well area 1aW. Thereafter, the gate insulating film 201 may be formed on the first and second well areas 1aW and 1bW and the isolation structure IST. The gate insulating film 201 may cover the semiconductor material layer 208. Thereafter, the fifth gate conductive layer 207 may be formed on the isolation structure IST and the first well area 1aW. The fifth gate conductive layer 207 may be formed on a portion of the gate insulating film 201 on the isolation structure IST and a portion of the gate insulating film 201 on the first well area 1aW. Thereafter, the first gate conductive layer 202 may be formed on the first and second well areas 1aW and 1bW and the isolation structure IST. The first gate conductive layer 202 may be formed on a portion of the fifth gate conductive layer 207 on the isolation structure IST and a portion of the fifth gate conductive layer 207 on the first well area 1aW. Thereafter, the second gate conductive layer 203, the third gate conductive layer 204, the fourth gate conductive layer 205, and the cap layer 206 may be sequentially formed on the first and second well areas 1aW and 1bW and the isolation structure IST.

Thereafter, a hard mask film 209 and an insulating film 210 covering the cap layer 206 may be further formed on the first and second well areas 1aW and 1bW and the isolation structure IST. The hard mask film 209 may be, for example, a Spin on Hardmask (SOH). The insulating film 210 may include, for example, an insulating material such as silicon oxide. However, embodiments of the present disclosure are not limited thereto.

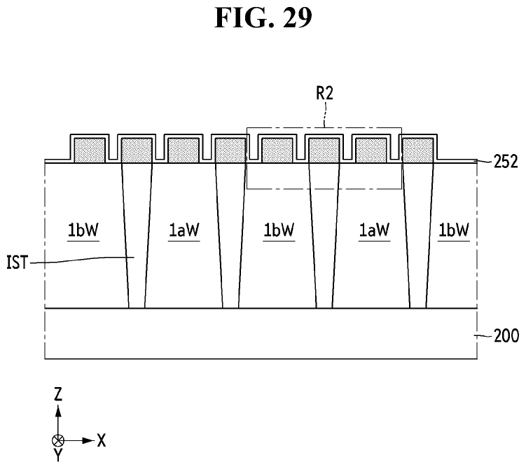

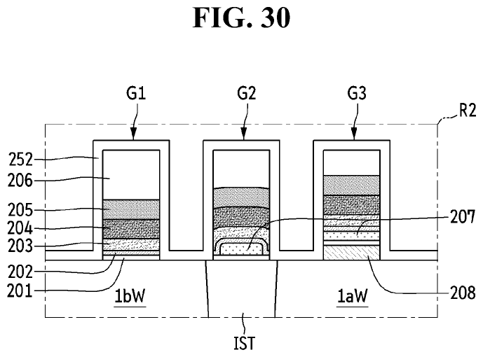

FIG. 30 is an enlarged view of an area R2 of FIG. 29.

Referring to FIGS. 29 and 30, the gate material layer GM of FIG. 27 may be patterned to form a first structure G1, a second structure G2, and a third structure G3.

Although not shown specifically, mask patterns (not shown) spaced apart from each other by a predetermined spacing may be formed on the insulating film (see FIG. 28). The gate material layer GM (see FIG. 27) may be patterned using the mask patterns (not shown). The patterning of the gate material layer (see FIG. 27) may be performed in a known etching process. Thereafter, the hard mask film 209 (see FIG. 28) and the insulating film 210 (see FIG. 28) may be removed to form the first structure G1, the second structure G2, and the third structure G3.

The capping film 252 may be formed along an upper surface of each of the first and second well areas 1aW and 1bW and the isolation structure IST and the sidewall and the upper surface of each of the first structure G1, the second structure G2, and the third structure G3. The capping film 252 may include, for example, silicon nitride. Thereafter, a portion of the capping film 252 formed on the upper surface of each of the first and second well areas 1aW and 1bW and the isolation structure IST may be removed. In some embodiments, a portion of the capping film 252 may remain on the upper surface of each of the first and second well areas 1aW and 1bW and the isolation structure IST.

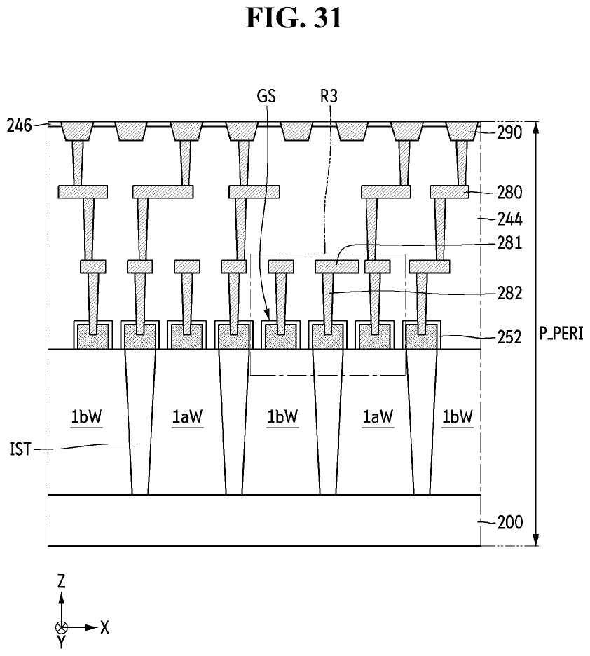

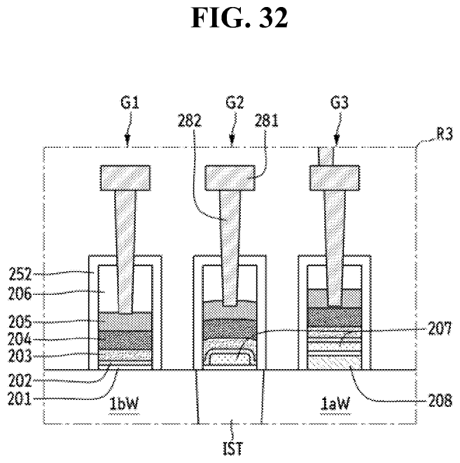

FIG. 32 is an enlarged view of an area R3 of FIG. 31.

Referring to FIGS. 31 and 32, the second interlayer insulating film 244 may be formed on the first and second well areas 1aW and 1bW and the isolation structure IST. The second through-via 282, the second wiring line 281, and the first wiring structure 280 may be formed in the second interlayer insulating film 244. The second bonding insulating layer 246 may be formed on the second interlayer insulating film 244, and the second bonding pad 290 may be formed in the second bonding insulating layer 246.

The second interlayer insulating film 244 may include an insulating material such as silicon oxide, and the second bonding insulating layer 246 may include silicon carbonitride. However, embodiments of the present disclosure are not limited thereto.

Each of the second through-via 282, the second wiring line 281, the first wiring structure 280, and the second bonding pad 290 may include a conductive material, for example, at least one of aluminum (Al), copper (Cu), tungsten (W), molybdenum (Mo), cobalt (Co), ruthenium (Ru), and alloys thereof. However, embodiments of the present disclosure are not limited thereto.

The second through-via 282 may be disposed on the gate structures GS and partially extend into the gate structures GS. Specifically, the second through-via 282 may extend in the third direction Z so as to contact the fourth gate conductive layer 205 of each of the first structure G1, the second structure G2, and the third structure G3. However, embodiments of the present disclosure are not limited thereto. Accordingly, a pre-peripheral circuit area P_PERI may be formed.

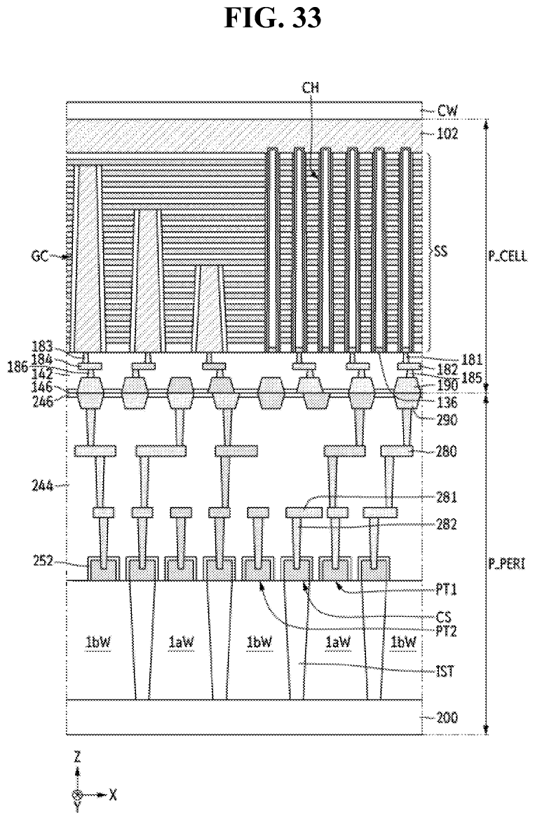

Referring to FIG. 33, a pre-memory cell area P_CELL may be stacked on the pre-peripheral circuit area P_PERI. The second bonding pad 290 of the pre-peripheral circuit area P_PERI and the first bonding pad 190 of the pre-memory cell area P_CELL may be disposed to face each other and may be bonded to each other.

The cell substrate 102 may be formed on the stack structure SS of the pre-memory cell area P_CELL. At least a portion of the channel structure CH may be disposed in the cell substrate 102.

Thereafter, a carrier substrate CW may be formed on a rear surface of the cell substrate 102. The carrier substrate CW may be formed on the pre-memory cell area P_CELL. The carrier substrate CW may include, for example, silicon and/or silicon oxide. Although not specifically shown, an adhesive layer including silicon carbonitride may be interposed between the cell substrate 102 and the carrier substrate CW.

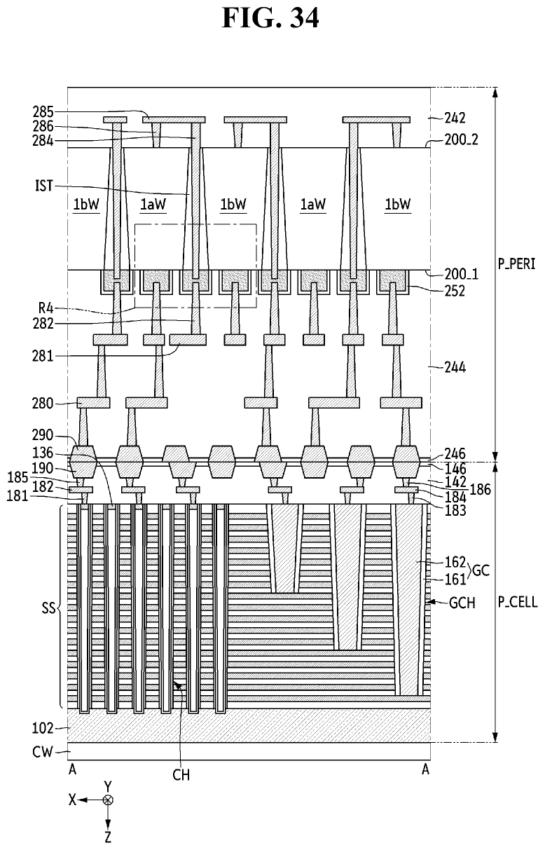

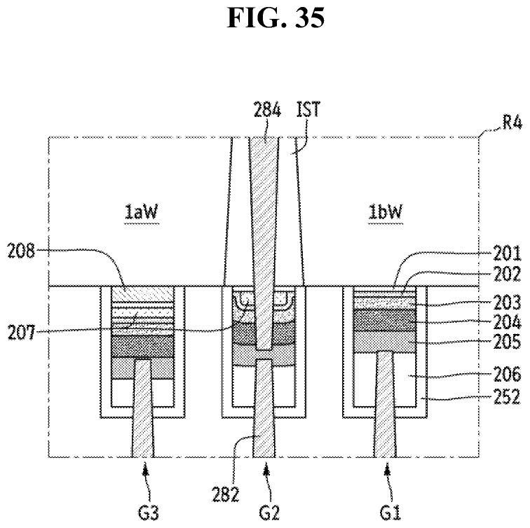

FIG. 35 is an enlarged view of an area R4 of FIG. 34.

Referring to FIGS. 34 and 35, the pre-peripheral circuit area P_PERI may be disposed on the pre-memory cell area P_CELL.

Grinding may be performed on the base substrate (see FIG. 33). Accordingly, at least a portion of the base substrate (see FIG. 33) may be removed. Although not shown specifically, a second guard area (see FIG. 19) for providing a second bias voltage to at least one of the first and second well areas 1aW and 1bW may be formed on the second surface 200_2 of the base substrate 200. In this case, the stopper structure CS of FIG. 19 may be electrically connected to the second guard area GB (see FIG. 19) via the second contact 286 of FIG. 19 on the second surface 200_2.

Thereafter, the first interlayer insulating film 242 may be formed on the isolation structure IST and the first and second well areas 1aW and 1bW from which the base substrate 200 (see FIG. 33) has been removed. The first interlayer insulating film 242 may include, for example, an insulating material such as silicon oxide. However, embodiments of the present disclosure are not limited thereto.

The first through-via 284, the first wiring line 285, and the second contact 286 may be formed in the first interlayer insulating film 242.

Each of the first through-via 284, the first wiring line 285, and the second contact 286 may include a conductive material, for example, at least one of aluminum (Al), copper (Cu), tungsten (W), molybdenum (Mo), cobalt (Co), ruthenium (Ru), or alloys thereof. However, embodiments of the present disclosure are not limited thereto.

The first through-via 284 may extend through the isolation structure IST. The first through-via 284 may extend in the third direction Z, for example, so as to contact the fourth gate conductive layer 205 of each of the first structure G1, the second structure G2, and the third structure G3. However, embodiments of the present disclosure are not limited thereto.

Thereafter, the input/output contact (see FIG. 4 or 19) may be formed in the first interlayer insulating film 242. The third interlayer insulating film 240 (see FIG. 4 or 19) and the input/output pad 287 (see FIG. 4 or 19) may be formed on the first interlayer insulating film 242. The input/output pad 287 of FIG. 4 or 19 may be connected to the first wiring line 285 via the input/output contact 288 of FIG. 4 or 19.

Thereafter, the carrier substrate CW may be removed.

Accordingly, the semiconductor memory device as described with reference to FIGS. 1 to 25 may be manufactured.

In the semiconductor device including the transistors respectively formed in the well areas and the isolation structure isolating the well areas from each other, the through-via extending through the isolation structure may be used to form an electrical path.

In some embodiments, a portion of the conductive material layer generated in the process of forming the gate of the transistor may be left and thus may be used as a stopper pad on which the through-via is landed. That is, the through-vias landing on the stopper pad may minimize bending of the through-vias due to the difficulty of the etching process of the via holes. Accordingly, the semiconductor memory device having improved electrical characteristics and reliability may be formed.

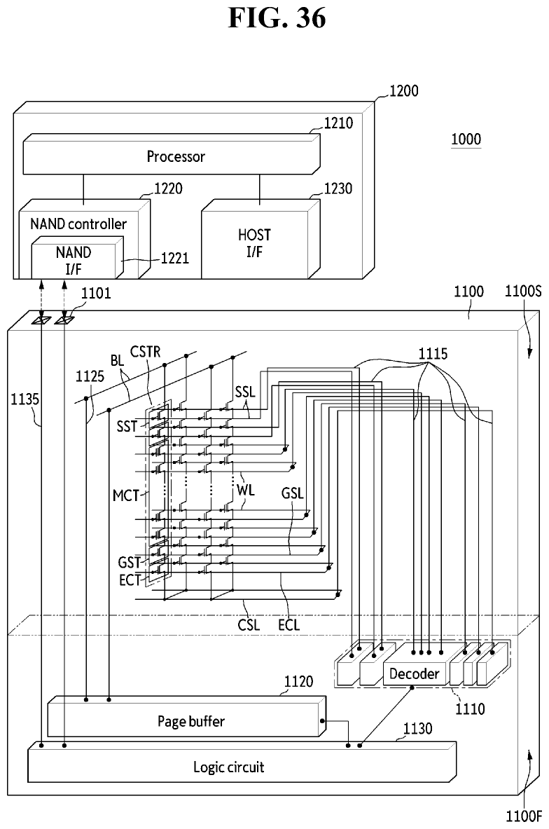

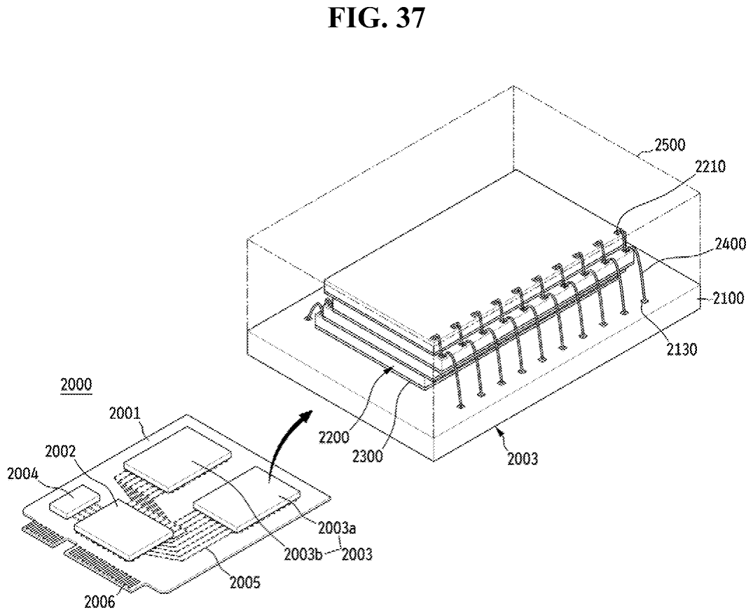

FIG. 36 is an example block diagram for illustrating an electronic system according to some embodiments. FIG. 37 is an example perspective view illustrating an electronic system according to some embodiments. For convenience of description, contents duplicative with contents described above with reference to FIGS. 1 to 35 will be briefly described or the descriptions thereof will be omitted for conciseness.

Referring to FIG. 36, an electronic system 1000 according to some embodiments may include a non-volatile memory device 1100 and a controller 1200 electrically connected to the non-volatile memory device 1100. The electronic system 1000 may be a storage device including one or a plurality of semiconductor memory devices 1100 or an electronic device including the storage device. For example, the electronic system 1000 may be embodied as a solid state drive device (SSD), a Universal Serial Bus (USB), a computing system, a medical device, or a communication device including one or a plurality of semiconductor memory devices 1100.

The non-volatile memory device 1100 may be embodied, for example, as a NAND flash memory device and may include, for example, the semiconductor memory device as described above with reference to FIGS. 1 to 35. The non-volatile memory device 1100 may include a first structure 1100F and a second structure 1100S on the first structure 1100F.

The first structure 1100F may be a peripheral circuit structure including a decoder circuit 1110 (for example, the row decoder 33 in FIG. 1), the page buffer 1120 (for example, the page buffer 35 in FIG. 1), and a logic circuit 1130 (for example, the control logic 37 of FIG. 1).

The second structure 1100S may include the common source line CSL, the plurality of bit-lines BL, and the plurality of cell strings CSTR as described above with reference to FIG. 2. The cell strings CSTR may be connected to the decoder circuit 1110 via the word-line WL, at least one string select line SSL, and at least one ground select line GSL. Further, the cell strings CSTR may be connected to the page buffer 1120 via the bit-lines BL.

In some embodiments, the common source line CSL and the cell strings CSTR may be electrically connected to the decoder circuit 1110 via first connection lines 1115 extending from the first structure 1100F to the second structure 1100S.

In some embodiments, the bit-lines BL may be electrically connected to the page buffer 1120 via second connection lines 1125 extending from the first structure 1100F to the second structure 1100S.

The non-volatile memory device 1100 may communicate with the controller 1200 via an input/output pad 1101 electrically connected to the logic circuit 1130 (e.g., the control logic 37 in FIG. 1). The input/output pad 1101 may be electrically connected to the logic circuit 1130 via an input/output connection line 1135 extending from the first structure 1100F to the second structure 1100S.

The controller 1200 may include a processor 1210, a NAND controller 1220, and a host interface 1230. In some embodiments, the electronic system 1000 may include a plurality of semiconductor memory devices 1100. In this case, the controller 1200 may control the plurality of semiconductor memory devices 1100.

The processor 1210 may control overall operations of the electronic system 1000 including the controller 1200. The processor 1210 may operate based on predefined firmware, and may control the NAND controller 1220 to access the non-volatile memory device 1100. The NAND controller 1220 may include a NAND interface 1221 that processes communication with the non-volatile memory device 1100. Via the NAND interface 1221, a control command for controlling the non-volatile memory device 1100, data to be written to memory cell transistors MCT of the non-volatile memory device 1100, and data to be read from the memory cell transistors MCT of the non-volatile memory device 1100 may be transmitted. The host interface 1230 may provide a communication function between the electronic system 1000 and an external host. Upon receiving a control command from an external host via the host interface 1230, the processor 1210 may control the non-volatile memory device 1100 in response to the control command.

Referring to FIG. 36 to FIG. 37, an electronic system according to some embodiments may include a main substrate 2001, a main controller 2002 mounted on the main substrate 2001, at least one semiconductor package 2003, and at least one DRAM 2004. The semiconductor package 2003 and he DRAM 2004 may be connected to the main controller 2002 via wiring patterns 2005 formed on the main substrate 2001.

The main substrate 2001 may include a connector 2006 including a plurality of pins coupled to an external host. The number and an arrangement of the plurality of pins in the connector 2006 may vary based on a communication interface between the electronic system 2000 and the external host. In some embodiments, the electronic system 2000 may communicate with the external host using one of interfaces such as USB (Universal Serial Bus), PCI-Express (Peripheral Component Interconnect Express), SATA (Serial Advanced Technology Attachment), M-Phy for UFS (Universal Flash Storage), etc. In some embodiments, the electronic system 2000 may operate using power supplied from the external host via the connector 2006. The electronic system 2000 may further include a power management integrated circuit (PMIC) for distributing power supplied from the external host to the main controller 2002 and the semiconductor package 2003.

The main controller 2002 may write data to the semiconductor package 2003 or read data from the semiconductor package 2003, and may improve an operating speed of the electronic system 2000.

The DRAM 2004 may act as a buffer memory for reducing a difference between operation speeds of the semiconductor package 2003 as a data storage space and the external host. The DRAM 2004 included in electronic system 2000 may operate as a cache memory, and may provide a space for temporarily storing data therein in a control operation of the semiconductor package 2003. When the DRAM 2004 is included in the electronic system 2000, the main controller 2002 may further include a DRAM controller for controlling the DRAM 2004 in addition to a NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be embodied as a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100 to each other, and a molding layer 2500 disposed the package substrate 2100 and covering the semiconductor chips 2200 and the connection structure 2400.

The package substrate 2100 may be embodied as a printed circuit board including package upper pads 2130. Each semiconductor chip 2200 may include an input/output pad 2210. The input/output pad 2210 may correspond to the input/output pad 1101 in FIG. 36.

In some embodiments, the connection structure 2400 may be embodied as a bonding wire that electrically connects the input/output pad 2210 and the package upper pads 2130 to each other. Accordingly, in each of the first semiconductor package 2003a and the second semiconductor package 2003b, the semiconductor chips 2200 may be electrically connected to each other in a bonding wire scheme, and may be electrically connected to the package upper pads 2130 of the package substrate 2100. In some embodiments, in each of the first semiconductor package 2003a and the second semiconductor package 2003b, the semiconductor chips 2200 may be electrically connected to each other via a connection structure including a through electrode (Through Silicon Via: TSV) instead of the connection structure 2400 using the bonding wire scheme.

In some embodiments, the main controller 2002 and the semiconductor chips 2200 may be included in one package. In some embodiments, the main controller 2002 and the semiconductor chips 2200 may be mounted on a separate interposer substrate different from the main substrate 2001, and the main controller 2002 and the semiconductor chips 2200 may be connected to each other via a wiring formed in the interposer substrate.

In the electronic system according to some embodiments, each of the semiconductor chips 2200 may include the semiconductor memory device described above with reference to FIGS. 1 to 35. For example, each of the semiconductor chips 2200 may include the peripheral circuit area PERI and the memory cell area CELL. For example, the peripheral circuit area PERI may include the first well area 1aW, the second well area 1bW, the isolation structure IST, the first transistor PT1, the second transistor PT2, the stopper structure CS, and the through-structure 284 and 282A, which are described above with reference to FIGS. 1 to 35. In addition, for example, the memory cell area CELL may include the cell substrate 102, the stack structure SS, the channel structure CH, the bit line 182, etc. as described above with reference to FIGS. 1 to 35.

The first well area 1aW may contain impurities of a first conductivity type, and the second well area 1bW may contain impurities of a second conductivity type different from the first conductivity type. The isolation structure IST may electrically isolate the first well area 1aW and the second well area 1bW from each other. The first transistor PT1 may be disposed on the first well area 1aW, and the second transistor PT2 may be disposed on the second well area 1bW. The stopper structure CS may be disposed on the isolation structure IST. The through-structure 284 and 282A may at least partially extend into the stopper structure CS in the vertical direction.

The through-structure 284 and 282A may include the first through-via 284 extending through the isolation structure IST and extending in the vertical direction, and the second through-via 282A extending in the vertical direction while being disposed on the first through-via 284.

The peripheral circuit area PERI may include the first guard (bias) area GB providing a first bias voltage to the first well area 1aW and the second guard (bias) area GB providing a second bias voltage to the second well area 1bW.

For example, the first transistor PT1 may be electrically connected to the decoder circuit (e.g., the decoder circuit 1110 of FIG. 35), and the second transistor PT2 may be electrically connected to the page buffer (e.g., the page buffer 1120 of FIG. 35). However, embodiments of the present disclosure are not limited thereto.

The stack structure SS may include a plurality of gate electrodes 112 disposed on the cell substrate 102 and extending in a first horizontal direction. The channel structure CH may extend in the stack structure SS in the vertical direction different from the first horizontal direction. The bit line 182 may extend in the second horizontal direction and may be electrically connected to the channel structure CH.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects and all such forms, changes, and modifications are intended to be included in the scope of the appended claims.

What is claimed is:

1. A semiconductor memory device comprising:
a cell area; and
a peripheral circuit area disposed on the cell area,
wherein the cell area includes:
a stack structure including a plurality of gate electrodes stacked in a first direction; and
a channel structure disposed in the stack structure and extending in the first direction, and
wherein the peripheral circuit area includes:
a well structure including a first surface and a second surface facing each other, wherein the well structure includes a first well area and a second well area disposed on the first surface, wherein a first transistor is disposed in the first well area, and a second transistor is disposed in the second well area;
an isolation structure that isolates the first well area and the second well area from each other;
a stopper structure disposed on the isolation structure; and
a through-structure that at least partially extends into the stopper structure in the first direction.

2. The semiconductor memory device of claim 1, wherein the peripheral circuit area further includes a first guard area disposed on the first surface and connected to at least one of the first well area or the second well area,
wherein the stopper structure is connected to the first guard area via the through-structure, a first wiring line connected to the through-structure, and a first contact connected to the first wiring line, and
wherein the first contact extends in the first direction.

3. The semiconductor memory device of claim 1, wherein the peripheral circuit area further includes a second guard area disposed on the second surface and connected to at least one of the first well area or the second well area,
wherein the stopper structure is connected to the second guard area via the through-structure, a second wiring line connected to the through-structure, and a second contact connected to the second wiring line, and
wherein the second contact extends in the first direction.

4. The semiconductor memory device of claim 1, wherein the stopper structure is disposed between the first well area and the second well area in a plan view.

5. The semiconductor memory device of claim 1, wherein the stopper structure is disposed around the first well area and the second well area in a plan view.

6. The semiconductor memory device of claim 1, wherein the through-structure includes:
a first through-via that extends through the isolation structure and extends in the first direction; and
a second through-via that is disposed on the first through-via and that extends in the first direction.

7. The semiconductor memory device of claim 6, wherein the first through-via is spaced apart from the second through-via in the stopper structure.

8. The semiconductor memory device of claim 6, wherein a width of the first through-via decreases as the first through-via extends toward the stopper structure in the first direction, and a width of the second through-via decreases as the second through-via extends toward the stopper structure in the first direction.

9. The semiconductor memory device of claim 6, wherein a vertical level in the first direction of the first through-via in the stopper structure is different from a vertical level in the first direction of the second through-via in the stopper structure.

10. The semiconductor memory device of claim 6, wherein the first through-via is in contact with the second through-via in the stopper structure.

11. The semiconductor memory device of claim 1, wherein the stopper structure includes a conductive material.

12. The semiconductor memory device of claim 1, wherein the first well area includes a n-conductivity material,
wherein the second well area includes a p-conductivity material,
wherein the first transistor is a PMOS transistor, and
wherein the second transistor is a NMOS transistor.

13. A semiconductor memory device comprising:
a cell area; and
a peripheral circuit area disposed on the cell area,
wherein the cell area includes:
a stack structure including a plurality of gate electrodes stacked in a first direction; and
a channel structure disposed in the stack structure and extending in the first direction, and
wherein the peripheral circuit area includes:
a well structure including a first well area of a first conductivity type and a second well area of a second conductivity type different from the first conductivity type;
an isolation structure disposed between the first well area and the second well area and including an insulating material;
a first transistor disposed on the first well area;
a second transistor disposed on the second well area;
a first interlayer insulating film disposed on the well structure, wherein a first wiring structure is disposed in the first interlayer insulating film;
a second interlayer insulating film disposed between the well structure and the cell area, wherein a second wiring structure is disposed in the second interlayer insulating film;
a conductive structure disposed on the isolation structure;
a first through-via that is disposed in the first interlayer insulating film and that extends in the first direction and contacts the conductive structure; and
a second through-via that is disposed in the second interlayer insulating film and that extends in the first direction and contacts the conductive structure.

14. The semiconductor memory device of claim 13, wherein the peripheral circuit area further includes a guard area that is disposed in the well structure and that is connected to at least one of the first well area or the second well area.

15. The semiconductor memory device of claim 14, wherein the guard area extends in a ring shape while being disposed in each of the first well area and the second well area in a plan view.

16. The semiconductor memory device of claim 14, wherein the guard area includes a plurality of guard areas arranged in a matrix form in a plan view.

17. The semiconductor memory device of claim 13, wherein in the conductive structure, the first through-via overlaps the second through-via in the first direction.

18. The semiconductor memory device of claim 13, wherein a length in the first direction of the first through-via is different than a length in the first direction of the second through-via.

19. A semiconductor memory device comprising:
a cell area; and
a peripheral circuit area disposed on the cell area,
wherein the cell area includes:
a stack structure including a plurality of gate electrodes stacked in a first direction;
a channel structure that is disposed in the stack structure and that extends in the first direction;
a bit line that extends in a second direction different from the first direction and that is connected to the channel structure; and
a first bonding pad disposed on the bit line, and
wherein the peripheral circuit area includes:
a well structure including a first well area of a first conductivity type and a second well area of a second conductivity type different from the first conductivity type;
an isolation structure that isolates the first well area from the second well area;
a PMOS transistor disposed on the first well area;
a NMOS transistor disposed on the second well area;
a first interlayer insulating film disposed on the well structure;
a second interlayer insulating film disposed between the well structure and the cell area;
a second bonding pad that is disposed on the second interlayer insulating film and that is bonded to the first bonding pad;
a bias structure including a first bias area connected to the first well area and a second bias area connected to the second well area;
a conductive structure disposed on the isolation structure;
a first through-via that is disposed in the first interlayer insulating film and that extends in the first direction and contacts the conductive structure; and
a second through-via that is disposed in the second interlayer insulating film and that extends in the first direction and contacts the conductive structure.

20. The semiconductor memory device of claim 19, wherein the first bias area includes a n-conductivity material, and
wherein the second bias area includes a p-conductivity material.
